(19) United States
(12) Patent Application Publication
(10) Pub. No.: US 2025/0258567 A1
(43) Pub. Date: Aug. 14, 2025

(54) DISPLAY DEVICE, DISPLAY PANEL AND VEHICLE

(71) Applicant: LG Display Co., Ltd., Seoul (KR)

(72) Inventors: In KANG, Paju-si (KR); Wooram OH, Paju-si (KR)

(21) Appl. No.: 19/010,783

(22) Filed: Jan. 6, 2025

(30) Foreign Application Priority Data
Feb. 13, 2024 (KR) 10-2024-0020524

(51) Int. Cl. G06F 3/041; G06F 3/044

(52) U.S. Cl. CPC G06F 3/0418; G06F 3/0446; G06F 2203/04107; G06F 2203/04111

(57) ABSTRACT

A display device according to example embodiments of the disclosure may comprise a display area where a plurality of subpixels and a plurality of touch electrodes are disposed, a first area where a plurality of data lines and a plurality of touch lines are disposed, a second area where a plurality of data pads and a plurality of touch pads are disposed, and a third area where a plurality of data link lines and a plurality of touch link lines are disposed, between the first area and the second area. The third area may include a fourth area between the plurality of data link lines and the plurality of touch link lines and where a shielding layer is disposed to overlap at least some of the plurality of data link lines.

### CROSS-REFERENCE TO RELATED APPLICATION

This application claims priority from and benefits to Korean Patent Application No. 10-2024-0020524, filed on Feb. 13, 2024, which is hereby incorporated in its entirety by reference for all purposes as if fully set forth herein.

### BACKGROUND

### Technical Field

Example embodiments of the disclosure relate to a display device and a display panel.

### Description of the Related Art

A vehicle is a means of transportation that may move people or loads by kinetic energy. Here, vehicles may include various types of transportation that may transport people, such as passenger cars, trucks, buses, aircraft, and ships.

For the safety and convenience of vehicle users, vehicles are equipped with various sensors and electronic devices, and come with diversified functions.

The description provided in the background section should not be assumed to be prior art merely because it is mentioned in or associated with the background section. The background section may include information that describes one or more aspects of the subject technology.

### BRIEF SUMMARY

The display device recognizes the user's finger touch or a pen touch on the display panel and performs input processing based on the recognized touch so as to provide various functions.

As an example, a display device capable of touch recognition may include a plurality of touch electrodes arranged or embedded in a display panel and detect the presence of the user's touch on the display panel and coordinates of a touch by detecting a touch signal transferred through a touch line.

When electromagnetic noise generated at the data line in the display device affects a touch line, touch performance may be deteriorated.

The inventors of the disclosure have invented a display device and a display panel, among others, capable of reducing touch noise and enhancing touch performance.

Embodiments of the disclosure may provide a display device and a display panel capable of reducing area noise and enhancing touch performance.

A display device according to example embodiments of the disclosure may comprise a display area where a plurality of subpixels and a plurality of touch electrodes are disposed, a first area where a plurality of data lines and a plurality of touch lines are disposed, a second area where a plurality of data pads and a plurality of touch pads are disposed, and a third area where a plurality of data link lines and a plurality of touch link lines are disposed, between the first area and the second area. The third area may include a fourth area between the plurality of data link lines and the plurality of touch link lines and where a shielding layer is disposed to overlap at least some of the plurality of data link lines.

A display device according to example embodiments of the disclosure may comprise a substrate, a first signal line disposed on the substrate, a first insulation layer disposed on the first signal line, a second insulation layer disposed on the first insulation layer, a second signal line disposed on the second insulation layer, a third insulation layer disposed on the second signal line, a bank disposed on the third insulation layer, an encapsulation layer present on the bank and including a dam, a buffer layer disposed on the encapsulation layer, a shielding layer disposed on the buffer layer, a fourth insulation layer disposed on the shielding layer, and a touch link line disposed on the fourth insulation layer.

A display panel according to example embodiments of the disclosure may comprise a display area where a plurality of subpixels and a plurality of touch electrodes are disposed, a first area where a plurality of data lines and a plurality of touch lines are disposed, a second area where a plurality of data pads and a plurality of touch pads are disposed, and a third area where a plurality of data link lines and a plurality of touch link lines are disposed, between the first area and the second area. The third area may include a fourth area between the plurality of data link lines and the plurality of touch link lines and where a shielding layer is disposed to overlap at least some of the plurality of data link lines.

According to example embodiments of the disclosure, it is possible to reduce noise and enhance touch performance.

According to example embodiments of the disclosure, it is possible to efficiently process a touch signal by enhancing touch performance and achieve low-power driving.

It is to be understood that both the foregoing general description and the following detailed description are example and explanatory and are intended to provide further explanation of the inventive concepts as claimed.

### DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure.

The above and other characteristics, features, and improvements of the disclosure will be more clearly understood from the following detailed description, taken in conjunction with the accompanying drawings, in which:

FIG. 1 is a view illustrating an example inside of a vehicle according to example embodiments of the disclosure;

FIG. 2 is a view illustrating a display device according to example embodiments of the disclosure;

FIG. 3 is a view illustrating an example of a display panel in which subpixels having different emission angles are arranged in a display device according to example embodiments of the disclosure;

FIG. 4 is a cross-sectional view illustrating an example of a unit subpixel according to example embodiments of the disclosure;

FIG. 5 is a view illustrating an example of a light emitting element according to example embodiments of the disclosure;

FIG. 6 is a cross-sectional view illustrating another example of a light emitting element in a display device according to example embodiments of the disclosure;

FIG. 7 is a circuit diagram illustrating an example of a unit subpixel according to example embodiments of the disclosure;

FIG. 8 is a view illustrating an example of a mutual capacitance-based touch sensing structure in a display device according to example embodiments of the disclosure;

FIG. 9 is a view illustrating an example of an arrangement of touch lines constituting a mutual capacitance-based touch sensing structure in a display device according to example embodiments of the disclosure;

FIG. 10 is a view illustrating an example of an arrangement of pads and signal lines in a third area in a display device according to example embodiments of the disclosure;

FIG. 11 is a view illustrating an example of a cross section of a display device according to example embodiments of the disclosure;

FIG. 12 is a plan view illustrating an example of a third area in a display device according to example embodiments of the disclosure;

FIG. 13 is a view illustrating a cross section of a portion of a fourth area in a display device according to example embodiments of the disclosure;

FIG. 14 is a plan view illustrating a Y-touch link line extending along a third area in a display device according to example embodiments of the disclosure;

FIG. 15 is a view illustrating a portion of a cross section taken along a direction in which a dam extends in a third area in a display device according to example embodiments of the disclosure;

FIG. 16 is a plan view illustrating a portion where a power line is disposed in a third area in a display device according to example embodiments of the disclosure; and

FIG. 17 is a plan view illustrating another example of a third area in a display device according to example embodiments of the disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Hereinafter, some embodiments of the disclosure will be described in detail with reference to example drawings. In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Advantages and features of the present disclosure, and implementation methods thereof will be clarified through following example embodiments described with reference to the accompanying drawings. The present disclosure may, however, be embodied in different forms and should not be construed as limited to example embodiments set forth herein. Rather, these example embodiments may be provided so that this disclosure may be sufficiently thorough and complete to assist those skilled in the art to fully understand the scope of the present disclosure.

The shapes (e.g., sizes, lengths, widths, heights, thicknesses, locations, radii, diameters, and areas), ratios, angles, numbers, and the like, which are illustrated in the drawings to describe various example embodiments of the present disclosure are merely given by way of example. Therefore, the present disclosure is not limited to the illustrations in the drawings.

Terms, such as “first,” “second,” “A,” “B,” “(A),” or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

The terms, such as “below,” “lower,” “above,” “upper” and the like, may be used herein to describe a relationship between item(s) as illustrated in the drawings. It will be understood that the terms are spatially relative and based on the orientation depicted in the drawings.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The word “example” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various example embodiments of the disclosure will be described in detail with reference to the accompanying drawings.

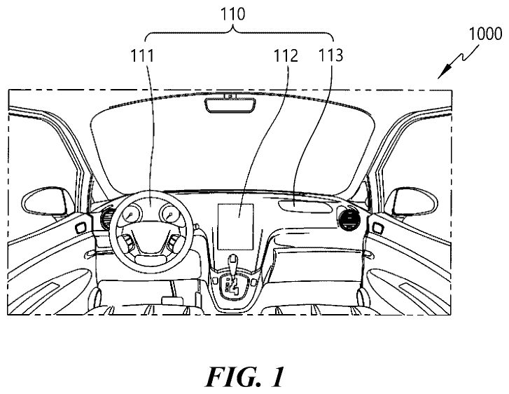

FIG. 1 is a view illustrating an example inside of a vehicle according to example embodiments of the disclosure.

Referring to FIG. 1, the vehicle 1000 according to example embodiments of the disclosure may include a driver seat and a passenger seat, a dashboard positioned in front of the driver seat and/or the passenger seat and on which various instruments for driving are disposed, and a center fascia having a control plate of an electronic device.

The functions of a vehicle may be divided into convenience functions for the convenience of the driver and safety functions for the safety of the driver or pedestrians, without being limited thereto.

The convenience functions include functions of providing the vehicle with information entertainment or autonomous driving functions, and helping the driver see at night or in blind spots. Examples of the convenience functions may include active cruise control (ACC), smart parking assist system (SPAS), night vision (NV), head up display (HUD), around view monitor (AVM), and adaptive headlight system (AHS), without being limited thereto.

The safety functions, which are techniques for ensuring the safety of the driver or pedestrians, may include functions, such as lane departure warning system (LDWS), lane keeping assist system (LKAS), and autonomous emergency braking (AEB), without being limited thereto.

Vehicles may be equipped with display devices including various types of display panels, and a vehicle control device may provide various convenience and safety functions to the driver or passengers by controlling information output to the internal display panel.

The dashboard may include a first display panel 111 that displays information for driving, for example, including a speedometer. The first display panel 111 may be referred to as a dashboard display panel.

The first display panel 111 is a display panel capable of safely driving the vehicle 1000 by transferring information about the driving state of the vehicle 1000 and operations of various electronic devices provided in the vehicle 1000 to the driver. A speedometer, for example, positioned behind the steering wheel with respect to the driver seat, to indicate the driving speed, a tripmeter indicating the driving distance, a tachometer indicating the revolutions per minute (RPM) of the engine, a fuel gauge, a water thermometer, an engine thermometer, and/or various warning lamps may be displayed through the first display panel 111.

The center fascia is, for example, positioned between the driver seat and the passenger seat, and may correspond to an area where the dashboard and the shift lever meet vertically, without being limited thereto, and an audio, an air conditioner, a heater controller, a navigator, a blower, a cup holder, or the like may be disposed therein, but embodiments of the disclosure are not limited thereto. Further, the center fascia may include a second display panel 112.

The second display panel 112 may direct a route to a destination or display a map image corresponding to a current location, and display a user interface related to control of various electronic devices installed in the vehicle 1000, without being limited thereto. Further, when the vehicle 1000 and the mobile terminal are connected, a screen provided by the mobile terminal may be displayed.

The second display panel 112 positioned between the driver seat and the passenger seat of the vehicle 1000 may be referred to as a center fascia display panel.

Further, as an example, a third display panel 113 for convenience of a passenger in the passenger seat may be further disposed on the front surface of the passenger seat. The third display panel 113 positioned in the passenger seat may be referred to as a passenger seat display panel.

Further, as an example, the display panel 110 may further include at least one of a front window display panel, a side mirror display panel, a rear-view mirror display panel, and a side window display panel, in addition to the dashboard display panel 111, the center fascia display panel 112, and the passenger seat display panel 113, but embodiments of the disclosure are not limited thereto. Further, various types of display panels may be installed.

The front window display panel may be a display panel that projects a virtual image to a partial area of the front window capable of viewing the front of the vehicle 1000. By displaying the speed of the vehicle, the remaining amount of fuel, the route direction information, or the like through the front window display panel, it is possible to reduce or minimize the driver's unnecessary gaze changing in different directions.

The side mirror display panel may be a display panel capable of displaying an image of a side surface captured through a side camera in a partial area or an entire area of the side mirror formed to view the side surface of the vehicle 1000. Accordingly, the driver may identify not only the image of the side surface reflected through the side mirror, but also the image of the side surface captured through the side camera through the side mirror display panel.

The rear-view mirror display panel may be a display panel capable of displaying an image of the rear captured by the rear camera in a partial area or an entire area of the rear-view mirror formed to view the rear of the vehicle 1000. Accordingly, the driver may identify not only the rear image reflected through the rear-view mirror, but also the rear image captured through the rear camera through the rear-view mirror display panel.

The side window display panel may be a display panel that projects a virtual image onto a partial area of the side window capable of viewing a side surface of the vehicle 1000. Various information about the vehicle may be displayed through the side window display panel. Embodiments are not limited thereto. As an example, at least one of the above mentioned display panels could be omitted depending on the design. As an example, at least one display panel may be additionally included.

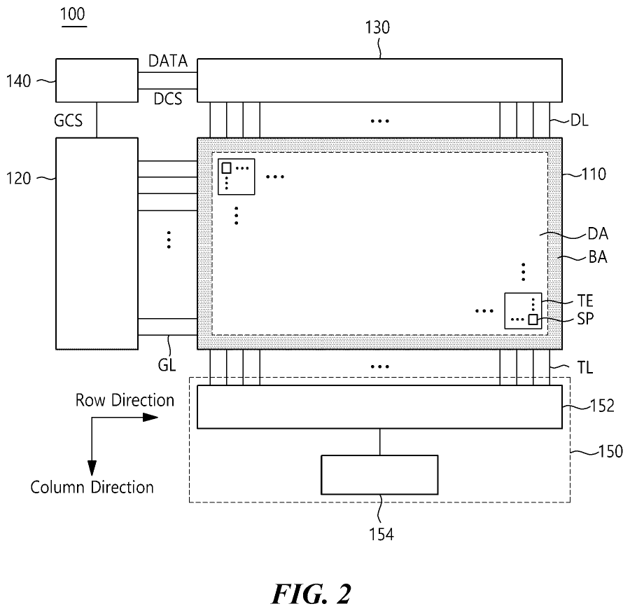

FIG. 2 is a view illustrating a display device according to example embodiments of the disclosure.

Referring to FIG. 2, a display device 100 according to example embodiments of the disclosure may include components for displaying an image. The display device 100 may include a display panel 110, a data driving circuit 130, a gate driving circuit 120, and a timing controller 140.

The display panel 110 may include a dashboard display panel 111, a center fascia display panel 112, and/or a passenger seat display panel 113, without being limited thereto.

The display panel 110 may include a display area DA in which images are displayed and a first area BA in which no image is displayed. The first area BA may be a bezel area, but embodiments of the disclosure are not limited thereto.

The first area BA may be an area outside the display area DA. The first area BA may be an area visible from the front of the display device 100 or an area that is bent and not visible from the front of the display device 100.

The display panel 110 may include a plurality of subpixels SP. For example, the display device 100 may be various types of display devices including a liquid crystal display device, an organic light emitting display device, a micro light emitting diode (micro LED) display device, a mini LED display device, and a quantum dot display device, but embodiments of the disclosure are not limited thereto.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors, but embodiments of the disclosure are not limited thereto.

The display panel 110 may further include various types of signal lines to drive the plurality of subpixels SP. For example, various types of signal lines may include a plurality of data lines DL transferring data signals (or referred to as data voltages or image data) and a plurality of gate lines GL transferring gate signals (or referred to as scan signals or emission signals).

The plurality of data lines DL and the plurality of gate lines GL may cross each other. Each of the plurality of data lines DL may be disposed while extending in a column direction. Each of the plurality of gate lines GL may be disposed while extending in a row direction.

The column direction and the row direction are relative. For example, the column direction may be a vertical direction and the row direction may be a horizontal direction. As another example, the column direction may be a horizontal direction and the row direction may be a vertical direction.

The data driving circuit 130 may be a circuit for driving a plurality of data lines DL. The data driving circuit 130 may output data signals to the plurality of data lines DL. The gate driving circuit 120 may be a circuit for driving a plurality of gate lines GL. The gate driving circuit 120 may supply gate signals to the plurality of gate lines GL.

The timing controller 140 may control the data driving circuit 130 and the gate driving circuit 120. The timing controller 140 may control driving timings for the plurality of data lines DL and driving timings for the plurality of gate lines GL.

The timing controller 140 may supply various types of data driving control signals DCS to the data driving circuit 130 to control the data driving circuit 130 and may supply various types of gate driving control signals GCS to the gate driving circuit 120 to control the gate driving circuit 120.

The data driving circuit 130 may supply data signals to the plurality of data lines DL according to the driving timing control by the timing controller 140. The data driving circuit 130 may receive digital image data DATA from the timing controller 140 and may convert the received image data DATA into analog data signals and output them to the plurality of data lines DL.

The data driving circuit 130 may be composed of a plurality of data driving integrated circuits (source driving integrated circuits SDIC), but the embodiments of the disclosure are not limited thereto.

The gate driving circuit 120 may supply gate signals to the plurality of gate lines GL according to the gate timing control of the timing controller 140. The gate driving circuit 120 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL. The turn-on level voltage may be a high level voltage, and the turn-off level voltage may be a low level voltage, without being limited thereto. As an example, the turn-on level voltage may be a low level voltage, and the turn-off level voltage may be a high level voltage.

To provide a touch sensing function as well as an image display function, the display device 100 may further include a touch screen panel and a touch circuit 150 that senses the touch screen panel to detect whether a touch occurs by a touch object, such as a finger or pen, or the position of the touch. Embodiments are not limited thereto. As an example, the display device 100 may not include the touch screen panel and the touch circuit 150, depending on the design.

The touch circuit 150 may include a touch driving circuit 152 that drives and senses the touch screen panel and generates and outputs touch sensing data and a touch controller 154 that may detect an occurrence of a touch or the position of the touch using the touch sensing data.

The touch screen panel may include a plurality of touch electrodes TE as touch sensors. The touch screen panel may further include a plurality of touch lines TL for electrically connecting the plurality of touch electrodes TE and the touch driving circuit 152. The touch screen panel or touch electrode TE may be a touch sensor.

The touch screen panel may be present outside or inside the display panel 110. When the touch screen panel is present outside the display panel 110, the touch screen panel is referred to as an external-type touch screen panel. When the touch screen panel is of the external type, the touch screen panel and the display panel 110 may be separately manufactured or may be combined. The external-type touch screen panel may include a substrate and a plurality of touch electrodes TE on the substrate.

When the touch screen panel is present inside the display panel 110, the touch screen panel is referred to as an internal-type touch screen panel. In the internal-type touch screen panel, the touch screen panel may be formed in the display panel 110 during a manufacturing process of the display panel 110.

The touch driving circuit 152 may supply a touch driving signal to at least one of the plurality of touch electrodes TE and detect a touch sensing signal transferred from at least one touch electrode TE among the plurality of touch electrodes TE, generating touch sensing data.

The touch driving circuit 152 may include a plurality of touch driving integrated circuits (read-out integrated circuits ROIC).

The touch circuit 150 may perform touch sensing in a self-capacitance sensing scheme or a mutual-capacitance sensing scheme, but embodiments of the disclosure are not limited thereto.

When the touch circuit 150 performs touch sensing in the self-capacitance sensing scheme, the touch circuit 150 may perform touch sensing based on capacitance between each touch electrode TE and the touch object (e.g., finger or pen).

When the touch circuit 150 performs touch sensing in the mutual-capacitance sensing scheme, the touch circuit 150 may perform touch sensing based on capacitance between the touch electrodes TE.

According to the mutual-capacitance sensing scheme, the plurality of touch electrodes TE may include touch driving electrodes and touch sensing electrodes. The touch driving circuit 152 may drive the touch driving electrode by the touch driving signal and may detect the touch sensing signal from the touch sensing electrode.

According to the self-capacitance sensing scheme, each of the plurality of touch electrodes TE may serve both as a touch driving electrode and as a touch sensing electrode. The touch driving circuit 152 may drive all or some of the plurality of touch electrodes TE and sense all or some of the plurality of touch electrodes TE.

The touch driving circuit 152 and the touch controller 154 may be implemented as separate devices or as a single device.

As an example, the touch driving circuit 152 and the data driving circuit 130 may be implemented as separate integrated circuits, without being limited thereto. As an example, the touch driving circuit 152 and the data driving circuit 130 may be integrated to be implemented as an integrated circuit.

The display device 100 according to example embodiments of the disclosure may be a self-emissive display device having self-emissive light emitting elements disposed on the display panel 110, such as an organic light emitting display device, a quantum dot display device, a micro LED display device, and the like.

The gate driving circuit 120 may include one or more gate driving integrated circuits GDIC. Depending on driving schemes, the gate driving circuit 120 may be positioned on only one side, or each of two opposite sides, of the display panel 110.

As an example, first subpixels and second subpixels having different emission angles may together be disposed on the display panel 110 of the disclosure, and the viewing angle of a video image may be controlled by selectively controlling the driving of the first subpixels or the second subpixels, without being limited thereto.

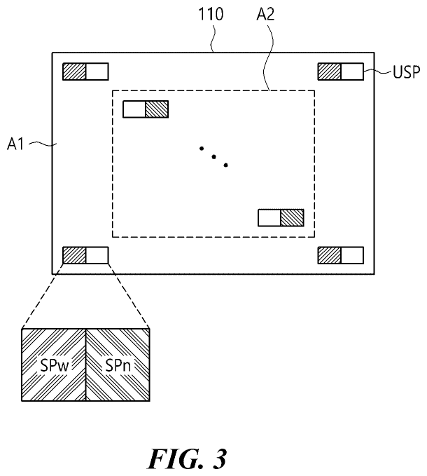

FIG. 3 is a view illustrating an example of a display panel in which subpixels having different emission angles are arranged in a display device according to example embodiments of the disclosure.

Referring to FIG. 3, in the display device 100 according to example embodiments of the disclosure, a plurality of unit subpixels USP may be disposed on the display panel 110.

As an example, the unit subpixel USP is a subpixel that emits light of a designated color, and may include a first subpixel SPw having a first emission angle and a second subpixel SPn having a second emission angle. The unit subpixel USP may include a unit subpixel emitting red light, a unit subpixel emitting green light, and a unit subpixel emitting blue light, but embodiments of the disclosure are not limited thereto. As an example, the unit subpixel USP may further include a unit subpixel emitting white light. As an example, the unit subpixel USP may alternatively or additionally include a unit subpixel emitting light of other colors other than red, green, blue and white. As an example, the unit subpixel USP may include only one subpixel with only one emission angle, or may include three or more subpixels having the same or different emission angles.

The first subpixel SPw may be a wide viewing angle subpixel having a wide emission angle, and the second subpixel SPn may be a narrow viewing angle subpixel having a narrow emission angle.

When the first subpixel SPw having a wide emission angle emits light from the unit subpixel USP disposed on the display panel 110, the video image of the display panel 110 may represent a wide viewing angle. Therefore, not only the driver in the vehicle but also the passenger in the passenger seat may recognize the video image of the display panel 110.

When the second subpixel SPn having a narrow emission angle emits light from the unit subpixel USP disposed on the display panel 110, the video image of the display panel 110 may represent a narrow viewing angle. Therefore, only the passenger (e.g., the driver) positioned in front of the display panel 110 in the vehicle 1000 may recognize the video image of the display panel 110. Embodiments are not limited thereto. As an example, even if the first subpixel SPw having a wide emission angle emits light, only the passenger (e.g., the driver) positioned in front of the display panel 110 in the vehicle 1000 may recognize the video image, or even if the second subpixel SPn having a narrow emission angle emits light, not only the driver in the vehicle but also the passenger in the passenger seat may recognize the video image of the display panel 110.

The area of the display panel 110 may be divided, and a video image having a different viewing angle may be displayed differently in each area, or a video image having the same viewing angle may be displayed in each area, without being limited thereto.

For example, the outer periphery of the display panel 110 may be set as a first area A1, and the unit subpixel USP positioned in the first area A1 may allow the first subpixel SPw having a wide emission angle to emit light. In this case, the video image displayed in the first area A1 may represent a wide viewing angle.

On the other hand, the central portion of the display panel 110 may be set as a second area A2, and the unit subpixel USP positioned in the second area A2 may allow the second subpixel SPn having a narrow emission angle to emit light. In this case, the video image displayed in the second area A2 may represent a narrow viewing angle.

The size of the second area A2 may be changed with respect to the center of the display panel 110. Accordingly, the first area A1 may be the remaining outer area other than the second area A2 in the display panel 110. Embodiments are not limited thereto. As an example, the dividing of the first area A1 and the second area A2 may be varied in various ways. As an example, the first area A1 may be a left area, and the second area A2 may be a right area, without being limited thereto.

The display device 100 according to the disclosure may selectively drive the subpixels SPw and SPn having different emission angles, thereby displaying a video image having different viewing angles according to the positions of the display panel 110.

The first subpixel SPw and the second subpixel SPn constituting the unit subpixel USP may have the same structure (size, number, position, etc.), but may also have different structures.

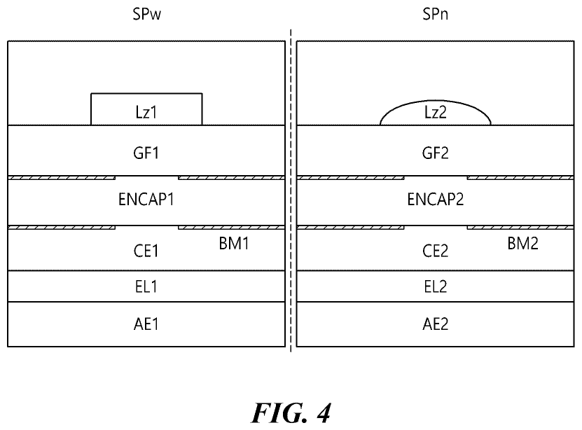

FIG. 4 is a cross-sectional view illustrating an example of a unit subpixel according to example embodiments of the disclosure.

Referring to FIG. 4, in the display device 100 according to an example embodiment of the disclosure, a unit subpixel disposed on a display panel 110 may include a first subpixel SPw having a first emission angle and a second subpixel SPn having a second emission angle.

The first emission angle emitted through the first subpixel SPw may be larger than the second emission angle emitted through the second subpixel SPn.

The first subpixel SPw may include a first anode electrode AE1, a first light emitting layer EL1, and a first cathode electrode CE1. The first anode electrode AE1, the first light emitting layer EL1, and the first cathode electrode CE1 may constitute a first light emitting element.

Further, a first black matrix BM1, a first insulation layer ENCAP1, a first gap filler GF1, and a first lens Lz1 having a first emission angle may be configured on the first cathode electrode CE1. An auxiliary gap filler may be further configured on the first lens Lz1. Embodiments are not limited thereto. As an example, at least one of the above-mentioned components may be omitted depending on the design. As an example, at least one component may be additionally or alternatively included.

A portion of the first black matrix BM1 overlapping the first anode electrode AE1 may be open.

The second subpixel SPn may include a second anode electrode AE2, a second light emitting layer EL2, and a second cathode electrode CE2. The second anode electrode AE2, the second light emitting layer EL2, and the second cathode electrode CE2 may constitute a second light emitting element.

Further, a second black matrix BM2, a second insulation layer ENCAP2, a second gap filler GF2, and a second lens Lz2 having a second emission angle may be configured on the second cathode electrode CE2. An auxiliary gap filler may be further configured on the second lens Lz2.

A portion of the second black matrix BM2 overlapping the second anode electrode AE2 may be open.

The first black matrix BM1 and the second black matrix BM2 may block light incident on the active layer of the driving thin film transistor constituting the subpixel to reduce or prevent leakage current.

The first anode electrode AE1 of the first subpixel SPw and the second anode electrode AE2 of the second subpixel SPn may be formed of the same material, in the same thickness, on the same layer in the same process, but embodiments of the disclosure are not limited thereto. The first anode electrode AE1 and the second anode electrode AE2 may be formed by a masking process using a photoresist, but embodiments of the disclosure are not limited thereto.

The first light emitting layer EL1 of the first subpixel SPw and the second light emitting layer EL2 of the second subpixel SPn may be formed of the same material, the same color, and the same thickness on the same layer in the same process, but embodiments of the disclosure are not limited thereto.

The first light emitting layer EL1 and the second light emitting layer EL2 may include a hole injection layer HIL, a hole transporting layer HTL, an electron blocking layer EBL, an emitting material layer EML, an electron transporting layer ETL, a hole blocking layer HBL, and/or an electron injection layer EIL, but embodiments of the disclosure are not limited thereto.

The first cathode electrode CE1 of the first subpixel SPw and the second cathode electrode CE2 of the second subpixel SPn may be formed of the same material, in the same thickness, on the same layer in the same process, but embodiments of the disclosure are not limited thereto.

The first cathode electrode CE1 and the second cathode electrode CE2 may be formed of an opaque metal material, e.g., at least one of aluminum (Al), tungsten (W), copper (Cu), molybdenum (Mo), chromium (Cr), tantalum (Ta), titanium (Ti), and an alloy formed from a combination thereof, but embodiments of the disclosure are not limited thereto. As an example, the first cathode electrode CE1 and the second cathode electrode CE2 may be formed of a transparent or opaque conduction materials.

The first gap filler GF1 of the first subpixel SPw and the second gap filler GF2 of the second subpixel SPn may be formed of the same material, in the same thickness, on the same layer in the same process, but embodiments of the disclosure are not limited thereto.

The separation distance between the first light emitting layer EL1 and the first lens Lz1 may be adjusted according to the thickness (or height) of the first gap filler GF1. Further, the separation distance between the second light emitting layer EL2 and the second lens Lz2 may be adjusted according to the thickness (or height) of the second gap filler GF2.

The first gap filler GF1 or the second gap filler GF2 may be formed by combining one or more materials of acrylic, epoxy, and silicone, but embodiments of the disclosure are not limited thereto. Alternatively, the first gap filler GF1 may be formed of an organic material, but embodiments of the disclosure are not limited thereto.

In the first gap filler GF1 or the second gap filler GF2, the particle size may be the same as the wavelength of light, or may be larger or smaller than the wavelength of light within a predetermined range. The first gap filler GF1 or the second gap filler GF2 may have a forward diffusion characteristic due to one of the density, size, and shape of the particle, but embodiments of the disclosure are not limited thereto.

The first gap filler GF1 and the second gap filler GF2 may have a refractive index smaller than that of the first insulation layer ENCAP1, but embodiments of the disclosure are not limited thereto. For example, the first gap filler GF1 and the second gap filler GF2 may have a refractive index smaller than that of the first insulation layer ENCAP1 by one of the density, size, and shape of the particle, but embodiments of the disclosure are not limited thereto.

The material of the first insulation layer ENCAP1 or the second insulation layer ENCAP2 may be one of TiO₂, Al₂O₃, and SiO₂, but embodiments of the disclosure are not limited thereto.

When the material of the first insulation layer ENCAP1 or the second insulation layer ENCAP2 is TiO₂, the material may have a refractive index in the range of 2.6 to 2.9. When the material of the first insulation layer ENCAP1 or the second insulation layer ENCAP2 is Al₂O₃, the material may have a refractive index in the range of 1.75 to 1.76. When the material of the first insulation layer ENCAP1 or the second insulation layer ENCAP2 is SiO₂, the material may have a refractive index in the range of 1.40 to 1.55.

The first lens Lz1 disposed on the first subpixel SPw having a wide emission angle may be a cylindrical lens, and the second lens Lz2 disposed on the second subpixel SPn having a narrow emission angle may be a circular lens, but embodiments of the disclosure are not limited thereto. As an example, as long as the second lens Lz2 disposed on the second subpixel SPn has a narrower emission angle than the first lens Lz1, the second lens Lz2 and the first lens Lz1 may have various shapes.

The first lens Lz1 of the first subpixel SPw and the second lens Lz2 of the second subpixel SPn may be formed of the same material, in the same thickness, on the same layer in the same process, or may be formed of different materials, in different thickness, on different layers or in different process, but embodiments of the disclosure are not limited thereto. For example, the first lens Lz1 and the second lens Lz2 may be formed in different shapes and different sizes.

The refractive indices of the first lens Lz1 and the second lens Lz2 may be determined according to the shape of the lens and the thickness (or height) of the first gap filler GF1.

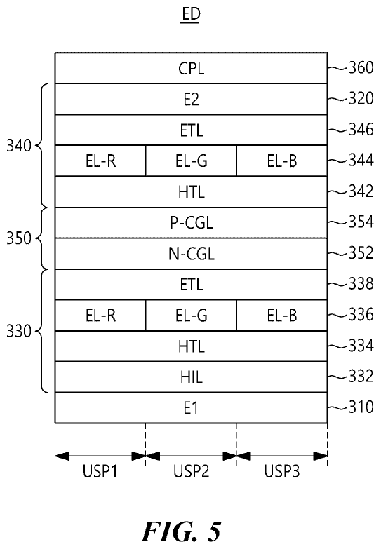

FIG. 5 is a view illustrating an example of a light emitting element according to example embodiments of the disclosure.

Referring to FIG. 5, in a display device 100 according to example embodiments of the disclosure, a light emitting element ED constituting a subpixel may include a first electrode 310 and a second electrode 320 facing each other, a first light emitting unit 330, a second light emitting unit 340, and a charge generation layer 350 positioned between the first electrode 310 and the second electrode 320.

The first electrode 310 is an anode electrode and may be formed of a conductive material having a relatively large work function value, but is not limited thereto. The second electrode 320 is a cathode electrode and may be formed of a conductive material having a relatively small work function value, but is not limited thereto.

The first light emitter 330 may include, but is not limited to, a hole injection layer 332, a first hole transporting layer 334, a first light emitting layer 336, and a first electron transporting layer 338.

The hole injection layer 332 may be between the first electrode 310 and the first light emitting layer 336. For example, the hole injection layer 332 may be formed of any one material among MTDATA(4,4′,4″-tris(N-3-methylphenyl-N-phenylamino)triphenylamine), CuPc(copper phthalocyanine), TCTA(tris(4-carbazoyl-9-ylphenyl)amine), NPB(N,N′-di(naphthalen-1-yl)-N,N′-diphenyl-benzidine), NPD(N,N-dinaphthyl-N,N′-diphenyl benzidine), HATCN(1,4,5,8,9,11-hexaazatriphenylene-hexanitrile), TDAPB(1,3,5-tris(4-diphenylaminophenyl)benzene), PEDOT/PSS(Poly(3,4-ethylene dioxythiophene)/polystyrene sulfonate), F4TCNQ(2,3,5,6-tetrafluoro-7,7,8,8-tetracyanl-quinidimethane), or N-(biphenyl-4-yl)-9,9-dimethyl-N-(4-(9-phenyl-9H-carbazole-3-yl)phenyl)-9H-fluorene-2-amine, but is not limited thereto.

The first hole transporting layer 334 may be present between the hole injection layer 332 and the first light emitting layer 336. The first light emitting layer 336 may be present between the first hole transporting layer 334 and the first electron transporting layer 338. Further, the first electron transporting layer 338 may be present between the first light emitting layer 336 and the charge generation layer 350.

The second light emitter 340 may include, but is not limited to, a second hole transporting layer 342, a second light emitting layer 344, and a second electron transporting layer 346.

The second light emitting layer 344 may be present between the second hole transporting layer 342 and the second electron transporting layer 346. The second electron transporting layer 346 may be present between the second light emitting layer 344 and the second electrode 320.

An electron injection layer may be further configured between the second electron transporting layer 346 and the second electrode 320. The electron injection layer may be formed of an alkali halide-based material such as LiF, CsF, NaF, BaF₂, and/or a material such as lithium quinolate (Liq), lithium benzoate, sodium stearate, or the like, but is not limited thereto.

Each of the first light emitting layer 336 and the second light emitting layer 344 may be formed by doping a host with a dopant, and may emit light of the same color or different colors.

For example, the first light emitting layer 336 and the second light emitting layer 344 each may include a red light emitting layer EL-R, a green light emitting layer EL-G, and a blue light emitting layer EL-B. The red light emitting layer EL-R may constitute a first subpixel area USP1 emitting red light, the green light emitting layer EL-G may constitute a second subpixel area USP2 emitting green light, and the blue light emitting layer EL-B may constitute a third subpixel area USP3 emitting blue light.

The first hole transporting layer 334 and the second hole transporting layer 342 may be formed of the same material or may be formed of different materials.

The first electron transporting layer 338 and the second electron transporting layer 346 may be formed of a material such as oxadiazole, triazole, phenanthroline, benzoxazole, benzothiazole, or benzimidazole (e.g., 2-[4-(9,10-Di-2-naphthalenyl-2-anthracenyl)phenyl]-1-phenyl-1H-benzimidazole), but are not limited thereto.

Each of the first electron transporting layer 338 and the second electron transporting layer 346 may include a dopant such as an alkali metal or an alkaline earth metal. The first electron transporting layer 338 and the second electron transporting layer 346 may be formed of the same material or different materials.

The charge generation layer 350 may be present between the first light emitting unit 330 and the second light emitting unit 340. The charge generation layer 350 may be disposed between the light emitting units to supply positive and negative charges to each light emitting unit.

The charge generation layer 350 may include an N-type charge generation layer N-CGL 352 adjacent to the first light emitting unit 330 and a P-type charge generation layer P-CGL 354 adjacent to the second light emitting unit 340. The N-type charge generation layer 352 may supply electrons to the first light emitting unit 330, and the P-type charge generation layer 354 may supply holes to the second light emitting unit 340.

The N-type charge generation layer 352 may be an organic layer doped with an alkali metal such as Li, Na, K, and Cs and/or an alkaline earth metal such as Mg, Sr, Ba, and Ra, but is not limited thereto.

A second hole injection layer may be further configured between the P-type charge generation layer 354 and the second hole transporting layer 342 or between the N-type charge generation layer 352 and the P-type charge generation layer 354. When the second hole injection layer is configured, holes generated in the P-type charge generation layer 354 may be efficiently injected and transferred to the second light emitting unit 340.

The first hole injection layer 332 and the second hole injection layer may be formed of the same material or different materials.

Further, the capping layer 360 is for increasing the light extraction effect of the light emitting element ED, and may be formed on the second electrode 320. The capping layer 360 may be formed of any one of materials constituting the first and second hole transporting layers 334 and 342 and materials constituting the first and second electron transporting layers 338 and 346, but embodiments of the disclosure are not limited thereto. As another example, the capping layer 360 may be formed of any one of host materials of the first light emitting unit 336 and the second light emitting unit 344, but embodiments of the disclosure are not limited thereto. Further, the capping layer 360 may be omitted.

Since the light emitting element ED having the tandem structure may decrease the driving voltage and emit white light, the light emitting element ED may be driven at a low voltage, and the life of the light emitting element ED may be enhanced and the luminous efficiency may be enhanced.

In the case of the display device 100 according to the disclosure, when the charge generation layer 350 is formed to be connected between adjacent subpixels without forming a step, a horizontal current may be generated from the charge generation layer 350 having high conductivity to the adjacent subpixels, causing light leakage in which unwanted subpixels emit light together.

When the charge generation layer 350 is formed with a step, horizontal current may be reduced or prevented from being generated due to the high conductivity of the charge generation layer 350, and as a result, light leakage in which unwanted adjacent subpixels emit light together may be reduced or prevented.

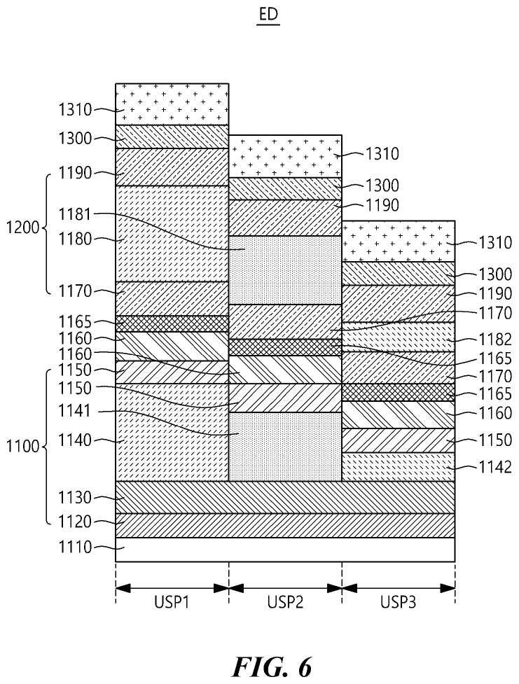

FIG. 6 is a cross-sectional view illustrating another example of a light emitting element in a display device according to example embodiments of the disclosure.

Referring to FIG. 6, a light emitting element ED of a display device 100 according to example embodiments of the disclosure may include light emitting units 1100 and 1200 between a first electrode 1100 and a second electrode 1300. The description included in FIG. 6 may be included in the description included in FIG. 5.

The first electrode 1110 may include indium-tin-oxide (ITO) and a silver (Ag) alloy, but is not limited thereto. For example, the ITO may be formed to have a thickness of 70 Å, a silver (Ag) alloy may be formed on the ITO to have a thickness of 1000 Å, and the ITO may then be formed on the silver alloy to have a thickness of 70 Å, but embodiments of the disclosure are not limited thereto.

A first light emitting unit 1100 may be disposed on the first electrode 1110. The first light emitting unit 1100 may include, but is not limited to, a hole injection layer 1120, a first hole transporting layer 1130, a light emitting layer, and a first electron transporting layer 1150.

A hole injection layer 1120 may be formed on the first electrode 1110. The hole injection layer 1120 may be formed of, e.g., HATCN (1,4,5,8,9,11-hexaazatriphenylene-hexanitrile), but embodiments of the disclosure are not limited thereto. For example, the hole injection layer 1120 may be formed to have a thickness of 70 Å, but embodiments of the disclosure are not limited thereto. A first hole transporting layer 1130 may be formed on the hole injection layer 1120. The first hole transporting layer 1130 may be formed of N-dinaphthyl-N,N′-diphenylbenzidine (NPD), or the like, but embodiments of the disclosure are not limited thereto. For example, the first hole transporting layer 1130 may be formed to have a thickness of 500 Å, but embodiments of the disclosure are not limited thereto.

The first light emitting layer 1140 may be formed in the red subpixel area USP1 above the first hole transporting layer 1130. The first light emitting layer 1140 may include at least one host and at least one dopant. For example, the host material may be formed of a beryllium (Be) compound derivative or the like, but embodiments of the disclosure are not limited thereto. For example, after the host material is formed to have a thickness of 650 Å, the first light emitting layer 1140 may be formed by doping with a dopant to a level of 5%, but embodiments of the disclosure are not limited thereto.

The first light emitting layer 1141 may be formed in the green subpixel area USP2 above the first hole transporting layer 1130. The first light emitting layer 1141 may include at least one host and at least one dopant. For example, the host material may be formed of carbazole biphenyl (CBP), but embodiments of the disclosure are not limited thereto. For example, after the host material is formed to have a thickness of 400 Å, the first light emitting layer 1141 may be formed by doping with a dopant to a level of 5%, but embodiments of the disclosure are not limited thereto.

The first light emitting layer 1142 may be disposed in the blue subpixel area USP3 above the first hole transporting layer 1130. The first light emitting layer 1142 may include at least one host and at least one dopant. For example, the host material may be formed of an anthracene derivative, but embodiments of the disclosure are not limited thereto. For example, after the host material is formed to have a thickness of 200 Å, the first light emitting layer 1142 may be formed by doping with a dopant to a level of 5%, but embodiments of the disclosure are not limited thereto.

For example, the thickness of the first light emitting layer 1140 may be larger than the thickness of the first light emitting layer 1141. For example, the thickness of the first light emitting layer 1140 may be larger than the thickness of the first light emitting layer 1142. For example, the thickness of the first light emitting layer 1141 may be larger than the thickness of the first light emitting layer 1142. For example, the thickness of the first light emitting layer 1140 may be larger than the thickness of each of the first light emitting layer 1141 and the first light emitting layer 1142. Embodiments are not limited thereto. As an example, at least one of first light emitting layer 1140, the first light emitting layer 1141, and the first light emitting layer 1142 may have a different thickness from others. As an example, two of the first light emitting layer 1140, the first light emitting layer 1141, and the first light emitting layer 1142 may have the same thickness, without being limited thereto.

A first electron transporting layer 1150 may be disposed on the first light emitting layer 1140, the first light emitting layer 1141, and the first light emitting layer 1142. For example, the first electron transporting layer 1150 may include an anthracene derivative and lithium quinolate (Liq), but embodiments of the disclosure are not limited thereto. For example, the anthracene derivative and lithium quinolate (Liq) may be mixed in a ratio of 1:1, but embodiments of the disclosure are not limited thereto. The first electron transporting layer 1150 may be formed to have a thickness of 70 Å, but embodiments of the disclosure are not limited thereto.

As another example, a hole blocking layer may be further formed under the first electron transporting layer 1150. The hole blocking layer may be formed on the first light emitting layer 1140, the first light emitting layer 1141, and the first light emitting layer 1142.

An N-type charge generation layer N-CGL 1160 may be formed as a charge generation layer on the first electron transporting layer 1150, and a P-type charge generation layer P-CGL 1165 may be formed on the N-type charge generation layer 1160. The N-type charge generation layer may be formed of Alq3 or the like, but embodiments of the disclosure are not limited thereto. For example, the N-type charge generation layer 1160 may be formed to have a thickness of 100 Å and then doped with lithium (Li), but embodiments of the disclosure are not limited thereto. The P-type charge generation layer 1165 may be formed of HATCN or the like on the N-type charge generation layer 1160, but embodiments of the disclosure are not limited thereto. The P-type charge generation layer 1165 may be formed to have a thickness of 100 Å to form a charge generation layer having a thickness of 200 Å, but embodiments of the disclosure are not limited thereto. As an example, the thickness of the N-type charge generation layer 1160, the P-type charge generation layer 1165 and the charge generation layer having a thickness of 200 Å may be varied in various ways. As an example, the charge generation layer may have a thickness less than, equal to or more than 200 Å.

The second light emitting unit 1200 may be disposed on the charge generation layer. The second light emitting unit 1200 may include a second hole transporting layer 1170, a light emitting layer, and a second electron transporting layer 1190, but is not limited thereto. For example, the charge generation layer may be formed between the first light emitting unit 1100 and the second light emitting unit 1200.

A second hole transporting layer 1170 may be formed on the charge generation layer. The second hole transporting layer 1170 may be formed of NPD or the like, but embodiments of the disclosure are not limited thereto. The second hole transporting layer 1170 may be formed to have a thickness of 400 Å, but embodiments of the disclosure are not limited thereto. For example, the thickness of the second hole transporting layer 1170 may be larger than or equal to the thickness of the first hole transporting layer 1130, but embodiments of the disclosure are not limited thereto.

The second light emitting layer 1180 may be formed in the red subpixel area USP1 above the second hole transporting layer 1170. The second light emitting layer 1180 may include at least one host and at least one dopant. The second light emitting layer 1180 may be formed of a beryllium (Be) complex derivative, which is a host material, but embodiments of the disclosure are not limited thereto. After the host material is formed to have a thickness of 650 Å, the second light emitting layer 1180 may be formed by doping with a dopant to a level of 5%, but embodiments of the disclosure are not limited thereto.

As another example, a hole transporting layer may be further disposed under the second light emitting layer 1180. The hole transporting layer may further enhance the luminous efficiency of the second light emitting layer 1180. The hole transporting layer may be disposed between the second hole transporting layer 1170 and the second light emitting layer 1180. For example, the hole transporting layer may be formed of the same material as the second hole transporting layer 1170, but embodiments of the disclosure are not limited thereto. For example, the thickness of the hole transporting layer may be larger than the thickness of the second hole transporting layer 1170, but embodiments of the disclosure are not limited thereto.

The second light emitting layer 1181 may be formed in the green subpixel area USP2 above the second hole transporting layer 1170. The second light emitting layer 1181 may include at least one host and at least one dopant. The second light emitting layer 1181 may be formed of a host material such as CBP, but embodiments of the disclosure are not limited thereto. After the host material is formed to have a thickness of 400 Å, the second light emitting layer 1181 may be formed by doping with a dopant to a level of 5%, but embodiments of the disclosure are not limited thereto.

The second light emitting layer 1182 may be formed in the blue subpixel area USP3 above the second hole transporting layer 1170. The second light emitting layer 1182 may include at least one host and at least one dopant. The second light emitting layer 1182 may be formed of an anthracene derivative, which is a host material, but embodiments of the disclosure are not limited thereto. After the host material is formed to have a thickness of 200 Å, the second light emitting layer 1182 may be formed by doping with a dopant to a level of 5%, but embodiments of the disclosure are not limited thereto.

For example, the thickness of the second light emitting layer 1180 may be larger than the thickness of the second light emitting layer 1181. For example, the thickness of the second light emitting layer 1180 may be larger than the thickness of the second light emitting layer 1182. For example, the thickness of the second light emitting layer 1181 may be larger than the thickness of the second light emitting layer 1182. For example, the thickness of the second light emitting layer 1180 may be larger than the thickness of each of the second light emitting layer 1181 and the second light emitting layer 1182. Embodiments are not limited thereto.

For example, the thickness of the first light emitting layer 1140 may be the same as or different from the thickness of the second light emitting layer 1180. For example, the thickness of the first light emitting layer 1141 may be the same as or different from the thickness of the second light emitting layer 1181. For example, the thickness of the first light emitting layer 1142 may be the same as or different from the thickness of the second light emitting layer 1182.

A second electron transporting layer 1190 may be formed on the second light emitting layer 1180, the second light emitting layer 1181, and the second light emitting layer 1182. The second electron transporting layer 1190 may be formed of an anthracene derivative, lithium quinolate (Liq), or the like, but embodiments of the disclosure are not limited thereto. For example, an anthracene derivative and lithium quinolate (Liq) may be mixed at a ratio of 1:1 to form a thickness of 300 Å, but embodiments of the disclosure are not limited thereto. For example, the thickness of the second electron transporting layer 1190 may be larger than or equal to the thickness of the first electron transporting layer 1150, but embodiments of the disclosure are not limited thereto.

For example, the light emitting layer of the first light emitting unit 1100 and the light emitting layer of the second light emitting unit 1200 may emit light of the same color. For example, the first light emitting layer 1140 of the first light emitting unit 1100 may emit light of the same color as the second light emitting layer 1180 of the second light emitting unit 1200. For example, the first light emitting layer 1141 of the first light emitting unit 1100 may emit light of the same color as the second light emitting layer 1181 of the second light emitting unit 1200. For example, the first light emitting layer 1142 of the first light emitting unit 1100 may emit light of the same color as the second light emitting layer 1182 of the second light emitting unit 1200.

As another example, a hole blocking layer may be further formed under the second electron transporting layer 1190. The hole blocking layer may be formed on the second light emitting layer 1180, the second light emitting layer 1181, and the second light emitting layer 1182.

A second electrode 1300 may be formed on the second electron transporting layer 1190. For example, the second electrode 1300 may be formed of a magnesium-silver alloy (Mg:Ag) in which magnesium (Mg) and silver (Ag) are mixed at a ratio of 9:1 and may be formed to have a thickness of 140 Å, but embodiments of the disclosure are not limited thereto. The second electrode 1300 may be a transflective electrode. Embodiments are not limited thereto. As an example, the second electrode 1300 may be a transparent electrode, a semi-transparent electrode or an opaque electrode.

A capping layer 1310 may be formed on the second electrode 1300. The capping layer 1310 may be formed of one or more layers, but embodiments of the disclosure are not limited thereto. The capping layer 1310 may reduce or minimize damage to the second electrode 1300 of the light emitting element ED and organic material layers under the second electrode 1300 from an external environment. The capping layer 1310 may be formed of an organic or inorganic film. The capping layer 1310 may be formed of an inorganic film using a material such as LiF, and may further include an organic film, but embodiments of the disclosure are not limited thereto. For example, the capping layer 1310 may be formed of a stacked structure of an organic film and an inorganic film, and the thickness of the organic film and the thickness of the inorganic film may be different or may be the same. For example, the thickness of the organic film may be larger than the thickness of the inorganic film. As another example, the capping layer 1310 may be formed of two or more layers by stacking materials having different refractive indices. Accordingly, the light efficiency of the display device may be enhanced. Embodiments are not limited thereto. As an example, the capping layer 1310 may be formed of two or more layers by stacking materials having the same refractive index, without being limited thereto.

Regarding steps between the subpixels of the light emitting element ED with respect to the first electrode 1110, the step between the first light emitting layer 1140 and the first light emitting layer 1141 may be formed at a level of 250 Å, and the step between the first light emitting layer 1141 and the first light emitting layer 1142 may be formed at a level of 200 Å. Further, the step difference between the first light emitting layer 1142 and the first light emitting layer 1140 may be formed at a level of 450 Å. Embodiments are not limited thereto. As an example, the steps between the subpixels of the light emitting element ED with respect to the first electrode 1110 may be varied in various ways. As an example, the step difference between the first light emitting layer 1142 and the first light emitting layer 1140 may be the summation between the step between the first light emitting layer 1140 and the first light emitting layer 1141 and the step between the first light emitting layer 1141 and the first light emitting layer 1142, without being limited thereto. As an example, the step between the first light emitting layer 1140 and the first light emitting layer 1141, the step between the first light emitting layer 1141 and the first light emitting layer 1142, and the step between the first light emitting layer 1142 and the first light emitting layer 1140 are formed at a level equal to or greater than the thickness of the N-type charge generation layer 1160, the P-type charge generation layer 1165 and the charge generation layer, without being limited thereto.

In the light emitting element ED of the disclosure, as the step between the first light emitting layer 1140 and the first light emitting layer 1141, the step between the first light emitting layer 1141 and the first light emitting layer 1142, and the step between the first light emitting layer 1142 and the first light emitting layer 1140 are formed, the charge generation layers 1160 formed in the red, green, and blue subpixel areas above the light emitting layer may also have a step therebetween. For example, in the light emitting element ED according to the disclosure, as the step between the first light emitting layer 1140 and the first light emitting layer 1141, the step between the first light emitting layer 1141 and the first light emitting layer 1142, and the step between the first light emitting layer 1142 and the first light emitting layer 1140 are all formed at a level of 200 Å or more, the charge generation layers formed in the red, green, and blue subpixel areas above the light emitting layer may also have a step of 200 Å or more. Embodiments are not limited thereto. As an example, at least one of the step between the first light emitting layer 1140 and the first light emitting layer 1141, the step between the first light emitting layer 1141 and the first light emitting layer 1142, and the step between the first light emitting layer 1142 and the first light emitting layer 1140 may be less than 200 Å.

Accordingly, the charge generation layer of the red subpixel area USP1, the charge generation layer 1160 of the green subpixel area USP2, and the charge generation layer of the blue subpixel area USP3 are not substantially connected to each other. The charge generation layer being not substantially connected between the two subpixel areas may mean that the charge generation layer formed in each subpixel area is open-circuited by a step, and that even when the charge generation layer is not open-circuited, a horizontal current hardly flows. Accordingly, the charge generation layer may be substantially open-circuited by a step.

The light emitting element ED constituting the display device 100 of the disclosure may not generate a horizontal current due to the high conductivity of the charge generation layer, thereby reducing or preventing light leakage in which unwanted adjacent subpixels emit light together.

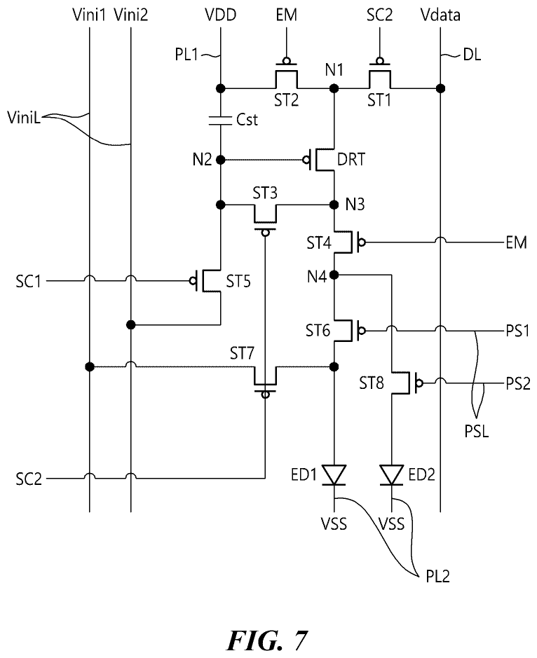

FIG. 7 is a circuit diagram illustrating an example of a unit subpixel according to example embodiments of the disclosure.

Referring to FIG. 7, a unit subpixel USP according to an example embodiment of the disclosure may include a first light emitting element ED1, a second light emitting element ED2, a driving transistor DRT, and an internal compensation circuit, without being limited thereto.

The first light emitting element ED1 may be disposed in the first subpixel SPw, and the second light emitting element ED2 may be disposed in the second subpixel SPn, without being limited thereto.

A first lens Lz1 may be disposed on the first light emitting element ED1, and a second lens Lz2 may be disposed on the second light emitting element ED2.

The switching transistors ST1 to ST8 and DRT disposed in the unit subpixel may be implemented as PMOS-type low temperature poly silicon (LTPS) transistors, thereby securing a desired response characteristic.

For example, at least one of the switching transistors ST1 to ST8 may be implemented as an NMOS-type or PMOS-type oxide transistor having good leakage current characteristics when turned off, and the remaining transistors may be implemented as PMOS-type LTPS transistors having good response characteristics, but embodiments of the disclosure are not limited thereto. As an example, any of the switching transistors ST1 to ST8 may be implemented as an NMOS-type or PMOS-type transistor including semiconductors of oxide semiconductors, poly silicon, amorphous silicon, compound semiconductors, organic semiconductors, etc., without being limited thereto.

The unit subpixel may include a first switching transistor ST1 connected to the data line DL to transfer the data voltage Vdata by the second scan signal SC2.

The unit subpixel may include a second switching transistor ST2 connected to a first power line PL1 supplying the high potential pixel voltage VDD to transfer a high potential pixel voltage VDD by a light emitting signal EM.

The driving transistor DRT may connect the first node N1 and the third node N3. The driving transistor DRT may receive a voltage charged in the storage capacitor Cst as a gate voltage through the second node N2. The first node N1 may be shared by the first switching transistor ST1 and the second switching transistor ST2.

A fourth switching transistor ST4 may be connected between the third node N3 and the first light emitting element ED1. The fourth switching transistor ST4 may be controlled by the light emitting signal EM. The sixth switching transistor ST6 may be connected between the third node N3 and the first light emitting element ED1. The sixth switching transistor ST6 may be controlled by a first mode control signal PS1.

A fourth switching transistor ST4 may be connected between the third node N3 and the second light emitting element ED2. The fourth switching transistor ST4 may be controlled by the light emitting signal EM. The eighth switching transistor ST8 may be connected to the fourth node N4. The eighth switching transistor ST8 may be controlled by the second mode control signal PS2.

Accordingly, in a state in which the fourth switching transistor ST4 is turned on by the light emitting signal EM, the first light emitting element ED1 or the second light emitting element ED2 may emit light by the first mode control signal PS1 and the second mode control signal PS2.

The third switching transistor ST3 may connect the second node N2 and the third node N3. The third switching transistor ST3 may be controlled by the second scan signal SC2.

The fifth switching transistor ST5 may be connected between the second node N2 and the initialization voltage line ViniL. The initialization voltage line ViniL may supply the second initialization voltage Vini2. The fifth switching transistor ST5 may be controlled by the first scan signal SC1. Accordingly, the fifth switching transistor ST5 may initialize the gate node of the driving transistor DRT to the second initialization voltage Vini2 by the first scan signal SC1.

The seventh switching transistor ST7 may be connected between the anode electrode of the first light emitting element ED and the initialization voltage line ViniL, and the initialization voltage line ViniL may supply the first initialization voltage Vini1. The seventh switching transistor ST7 may be controlled by the second scan signal SC2. Accordingly, the seventh switching transistor ST7 may initialize the anode electrode of the first light emitting element ED1 to the first initialization voltage Vini1 by the second scan signal SC2.

The first light emitting element ED1 and the second light emitting element ED2 may emit light with an amount of current adjusted according to the voltage Vgs between the gate node and the source node of the driving transistor DRT.

The first light emitting element ED1 may be connected to the driving transistor DRT through the fourth switching transistor ST4 and the sixth switching transistor ST6. The second light emitting element ED2 may be connected to the driving transistor DRT through the fourth switching transistor ST4 and the eighth switching transistor ST8.

The cathode electrodes of the first light emitting element ED1 and the second light emitting element ED2 may be connected to the second power line PL2 supplying the low-potential pixel voltage VSS.

The driving transistor DRT may adjust the driving current flowing through the first light emitting element ED1 or the second light emitting element ED2 according to the voltage Vgs between the gate node and the source node.

The compensation circuit may be for sampling the voltage Vgs between the gate node and the source node of the driving transistor DRT to compensate for a threshold voltage change of the driving transistor DRT. The compensation circuit may include first to eighth switching transistors ST1 to ST8 and a storage capacitor Cst. Alternatively, the rest except for the first switching transistor ST1 for applying the data voltage Vdata may be referred to as a compensation circuit.

Accordingly, the unit subpixel constituting the display device 100 of the disclosure may control the light emission of the first light emitting element ED1 by the first mode control signal PS1, and control the light emission of the second light emitting element ED2 by the second mode control signal PS2.

For example, in the period in which the first light emitting element ED1 emits light, the first mode control signal PS1 may be supplied at a turn-on level (e.g., a low level), and the second mode control signal PS2 may be supplied at a turn-off level (e.g., a high level).

The gate driving circuit 120 may be implemented in the form of a gate in panel (GIP) directly formed in the non-display area NDA of the display panel 110 or in the form of a gate in array formed in the display area DA of the display panel 110, but embodiments of the disclosure are not limited thereto. As an example, the gate driving circuit 120 may be separately disposed in a separate panel and connected to the display panel 110, for example, in a tape automated bonding (TAB) method, a chip on glass (COG) method, a chip on panel (COP) method, or a chip on film (COF) method, without being limited thereto.

The display device 100 according to the disclosure may further provide a touch sensing function as well as an image display function.

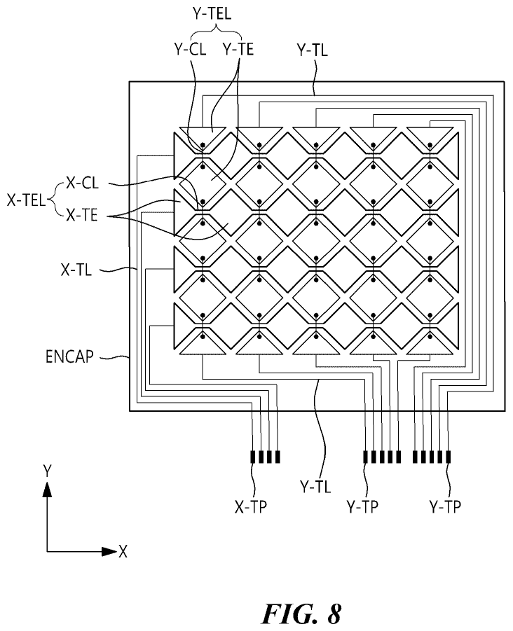

FIG. 8 is a view illustrating an example of a mutual capacitance-based touch sensing structure in a display device according to example embodiments of the disclosure.

Referring to FIG. 8, in a display device 100 according to example embodiments of the disclosure, a mutual capacitance-based touch sensing structure may include a plurality of X-touch electrode lines XTEL and a plurality of Y-touch electrode lines Y-TEL. The plurality of X-touch electrode lines X-TEL and the plurality of Y-touch electrode lines Y-TEL may be positioned on an encapsulation layer ENCAP. The touch sensing structure is not limited thereto.

The plurality of X-touch electrode lines X-TEL may be disposed in a first direction, and the plurality of Y-touch electrode lines Y-TEL may be disposed in a second direction different from the first direction.

Here, the first direction and the second direction may be relatively different directions, and for example, the first direction may be an x-axis direction and the second direction may be a y-axis direction. Alternatively, the first direction may be the y-axis direction, and the second direction may be the x-axis direction. The first direction and the second direction may be, or may not be, perpendicular to each other.

The plurality of X-touch electrode lines X-TEL may include several electrically connected X-touch electrodes X-TE, and the plurality of Y-touch electrode lines Y-TEL may include several electrically connected Y-touch electrodes Y-TE.

The plurality of X-touch electrodes X-TE and the plurality of Y-touch electrodes Y-TE may be electrodes included in the plurality of touch electrodes TE and have distinct roles (functions). For example, the plurality of X-touch electrodes X-TE constituting the plurality of X-touch electrode lines X-TEL may be touch driving electrodes, and the plurality of Y-touch electrodes Y-TE constituting the plurality of Y-touch electrode lines Y-TEL may be touch sensing electrodes. In this case, the plurality of X-touch electrode lines X-TEL may correspond to touch driving electrode lines, and the plurality of Y-touch electrode lines Y-TEL may correspond to touch sensing electrode lines.

Conversely, the plurality of X-touch electrodes X-TE constituting the plurality of X-touch electrode lines X-TEL may be touch sensing electrodes, and the plurality of Y-touch electrodes Y-TE constituting the plurality of Y-touch electrode lines Y-TEL may be touch driving electrodes. In this case, the plurality of X-touch electrode lines X-TEL may correspond to touch sensing electrode lines, and the plurality of Y-touch electrode lines Y-TEL may correspond to touch driving electrode lines.

A touch sensor metal for touch sensing may include a plurality of touch lines TL as well as the plurality of X-touch electrode lines X-TEL and the plurality of Y-touch electrode lines Y-TEL.

The plurality of touch lines TL may include a plurality of X-touch lines X-TL connected to the plurality of X-touch electrode lines X-TEL, and a plurality of Y-touch lines Y-TL connected to the plurality of Y-touch electrode lines Y-TEL.

Each of the plurality of X-touch electrode lines X-TEL may include a plurality of X-touch electrodes X-TE disposed in the same row, and one or more X-touch electrode connection lines X-CL electrically connecting the plurality of X-touch electrodes X-TE. Here, the X-touch electrode connection line X-CL connecting two adjacent X-touch electrodes X-TE may be a metal integrated with the two adjacent X-touch electrodes X-TE, or a metal connected to the two adjacent X-touch electrodes X-TE through a contact hole.

The plurality of Y-touch electrode lines Y-TEL may include a plurality of Y-touch electrodes Y-TE disposed in the same column, and one or more Y-touch electrode connection lines Y-CL electrically connecting the plurality of Y-touch electrodes Y-TE. Here, the Y-touch electrode connection line Y-CL connecting two adjacent Y-touch electrodes Y-TE may be a metal integrated with the two adjacent Y-touch electrodes Y-TE or a metal connected to the two adjacent Y-touch electrodes Y-TE through a contact hole, but embodiments of the disclosure are not limited thereto.

In an area where the X-touch electrode line X-TEL and the Y-touch electrode line Y-TEL cross each other (a touch electrode line crossing area), the X-touch electrode connection line X-CL and the Y-touch electrode connection line Y-CL may cross each other.

As described above, when the X-touch electrode connection line X-CL and the Y-touch electrode connection line Y-CL cross each other in the touch electrode line crossing area, the X-touch electrode connection line X-CL and the Y-touch electrode connection line Y-CL may be positioned on different layers. Accordingly, in order for the plurality of X-touch electrode lines X-TEL and the plurality of Y-touch electrode lines Y-TEL to be disposed to cross each other, the plurality of X-touch electrodes X-TE, the plurality of X-touch electrode connection lines X-CL, the plurality of Y-touch electrodes Y-TE, and the plurality of Y-touch electrode connection lines Y-CL may be positioned on two or more layers, but embodiments of the disclosure are not limited thereto.

The plurality of X-touch electrode lines X-TEL are electrically connected to corresponding X-touch pads X-TP through one or more X-touch lines X-TL. As an example, the X-touch electrode X-TE disposed at the outermost among the plurality of X-touch electrodes X-TE included in one X-touch electrode line X-TEL may be electrically connected to the corresponding X-touch pad X-TP through the X-touch line X-TL.

The plurality of Y-touch electrode lines Y-TEL are electrically connected to corresponding Y-touch pads Y-TP through one or more Y-touch lines Y-TL. As an example, the Y-touch electrode Y-TE disposed at the outermost among the plurality of Y-touch electrodes Y-TE included in one Y-touch electrode line Y-TEL may be electrically connected to the corresponding Y-touch pad Y-TP through the Y-touch line Y-TL.

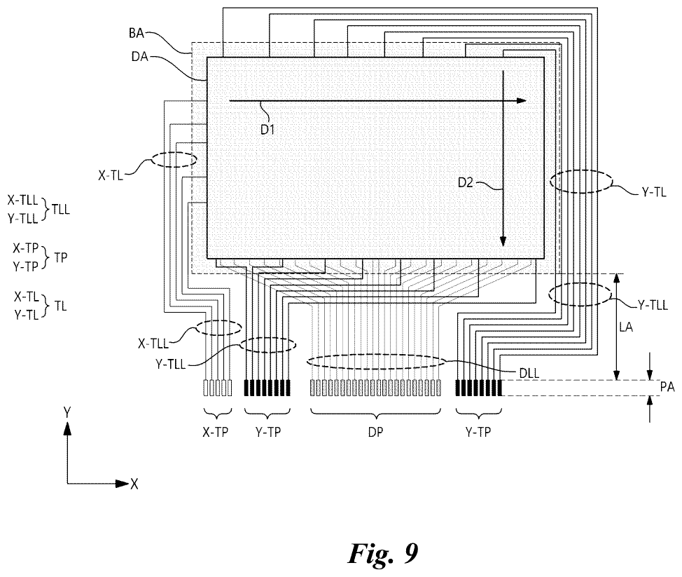

FIG. 9 is a view illustrating an example of an arrangement of touch lines constituting a mutual capacitance-based touch sensing structure in a display device according to example embodiments of the disclosure.

An example in which the X-touch electrode X-TE of FIG. 8 is used as a touch driving electrode and the Y-touch electrode Y-TE is used as a touch sensing electrode is illustrated, but embodiments of the disclosure are not limited thereto.

Accordingly, the X-touch electrode X-TE, the X-touch electrode connection line X-CL, the X-touch electrode line X-TEL, the X-touch line X-TL, and the X-touch pad X-TP may be referred to as a touch driving electrode, a touch driving electrode connection line, a touch driving electrode line, a touch driving line, and a touch driving pad, respectively, and the Y-touch electrode Y-TE, the Y-touch electrode connection line Y-CL, the Y-touch electrode line Y-TEL, the Y-touch line Y-TL, and the Y-touch pad Y-TP may be referred to as a touch sensing electrode, a touch sensing electrode connection line, a touch sensing electrode line, a touch sensing line, and a touch sensing pad, respectively.

Referring to FIG. 9, in the display device 100 according to example embodiments of the disclosure, a plurality of X-touch electrode lines X-TEL may be electrically connected to one or more X-touch lines X-TL for touch driving of the display panel 110. Each of the X-touch lines X-TL may be electrically connected to the touch driving circuit 152 through the X-touch pad X-TP.

For touch sensing of the display panel 110, a plurality of Y-touch electrode lines Y-TEL may be electrically connected to one or more Y-touch lines Y-TL. Each of the Y-touch lines Y-TL may be electrically connected to the touch driving circuit 152 through the Y-touch pad Y-TP.

The first direction D1 in which the plurality of X-touch electrode lines X-TEL extend may be referred to as a touch driving direction, and the second direction D2 in which the plurality of Y-touch electrode lines Y-TEL extend may be referred to as a touch sensing direction.

Meanwhile, in the display area DA of the display panel 110, a plurality of X-touch electrode lines X-TEL and a plurality of Y-touch electrode lines Y-TEL may be disposed together with the plurality of data lines DL and the plurality of gate lines GL.

A plurality of data pads DP, a plurality of X-touch pads X-TP, and a plurality of Y-touch pads Y-TP may be disposed in the second area PA. Further, as an example, for auto probe inspection, an inspection pad which a needle of the auto probe inspection device contacts may be further disposed, without being limited thereto.

A plurality of data link lines DLL connected to the plurality of data lines DL may be disposed in the third area LA between the display panel 110 and the second area PA. The plurality of data lines DL may be electrically connected to the data driving circuit 130 through a plurality of data link lines DLL. The data link line DLL may be a data line formed in the third area LA and may be formed of the same material as the data line DL, but embodiments of the disclosure are not limited thereto. The second area PA may be a pad area, but embodiments of the disclosure are not limited thereto. The third area LA may be a link area, but embodiments of the disclosure are not limited thereto.

Further, a plurality of touch link lines X-TLL and Y-TLL connected to the plurality of touch lines X-TL and Y-TL may be disposed in the third area LA between the display panel 110 and the second area PA. When the X-touch electrode X-TE is used as a touch driving electrode and the Y-touch electrode Y-TE is used as a touch sensing electrode, the X-touch link line X-TLL may be referred to as a touch driving link line, and the Y-touch link line Y-TLL may be referred to as a touch sensing link line.

The plurality of touch lines X-TL and Y-TL may be electrically connected to the touch driving circuit 152 through the plurality of touch link lines X-TLL and Y-TLL. The touch link lines X-TLL and Y-TLL may be viewed as touch lines X-TL and Y-TL formed in the third area LA, and may be formed of the same material as the touch lines X-TL and Y-TL, but embodiments of the disclosure are not limited thereto.

When the Y-touch electrode line Y-TEL for touch sensing extends in the second direction D2 in which the data line DL is disposed, the plurality of Y-touch link lines Y-TLL may be positioned on two opposite sides of the data link line DLL, and the plurality of X-touch link lines X-TLL may be disposed on the outermost side of the display panel 110. Embodiments are not limited thereto. As an example, the arrangement of the plurality of Y-touch link lines Y-TLL, the data link line DLL, and the plurality of X-touch link lines X-TLL may be varied in various way.

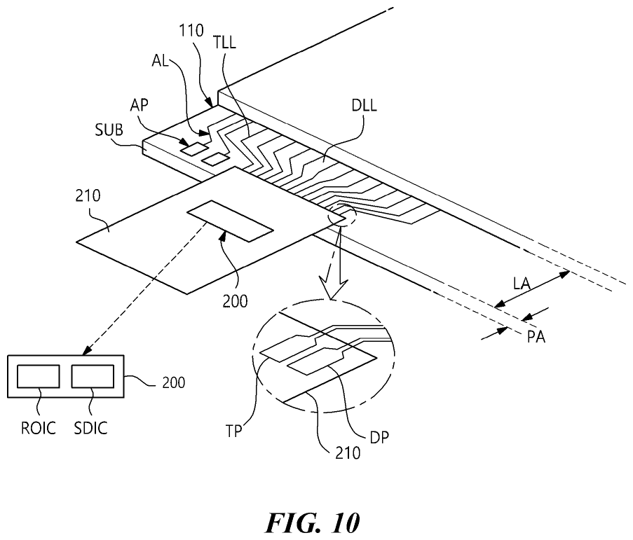

FIG. 10 is a view illustrating an example of an arrangement of pads and signal lines in a third area in a display device according to example embodiments of the disclosure.

Referring to FIG. 10, in a display device 100 according to example embodiments of the disclosure, at least one data driving integrated circuit SDIC and at least one touch driving integrated circuit ROIC may be integrated and implemented as one integrated circuit 200, but embodiments of the disclosure are not limited thereto.

The display device 100 may include one or more integrated circuits 200. Each integrated circuit 200 may include at least one data driving integrated circuit SDIC and at least one touch driving integrated circuit ROIC.

The integrated circuit 200 may be mounted on the circuit film 210. The circuit film 210 may be a film where the integrated circuit 200 may be mounted in a chip-on film (COF) manner.

The integrated circuit 200 may be formed on a film circuit board constituting the circuit film 210. The film circuit board of the circuit film 210 may be flexible. The film circuit board may be provided in various forms corresponding to the purpose and structure of the display panel 110.

One side of the plurality of circuit films 210 on which the plurality of integrated circuits 200 are mounted may be electrically connected to the display panel 110.

The other side of the circuit film 210 where the integrated circuit 200 is mounted may be electrically connected to the printed circuit board.

Further, a plurality of data pads DP and a plurality of touch pads TP may be disposed in the second area PA. Further, for an auto-probe inspection, an inspection pad AP which a needle of the auto-probe inspection device contacts may be further disposed, but embodiments of the disclosure are not limited thereto.

The inspection process may include, but is not limited to, an inspection of the driving circuit including the gate driving circuit 120, the data driving circuit 130, or the touch circuit 150, an inspection of the signal line such as the data line DL, the gate line GL, and the touch line TL formed on the substrate SUB, a subpixel inspection performed after the subpixel is formed, an electrical inspection performed after the substrate SUB is bonded, and/or a lighting inspection, without being limited thereto.

A repair process may be a process of repairing defects found by the inspection process.

In the auto probe inspection, a lighting inspection may be performed on the substrate SUB of the display panel 110 before the driving circuit is mounted to inspect a defect of a signal line or a thin film pattern on the substrate SUB.

In order to enable the auto probe inspection, an inspection pad AP which a needle of the auto probe inspection device contacts and an inspection line AL connected to the inspection pad AP may be formed on the substrate SUB.

The inspection pad AP may be disposed on a side surface of the circuit film 210 where the integrated circuit 200 is mounted, but embodiments of the disclosure are not limited thereto.

As an example, the inspection line AL for inspecting the touch line TL may be electrically connected to the X-touch link line X-TLL or the Y-touch link line Y-TLL in the third area LA, without being limited thereto.

The data line DL supplying the data voltage to the display panel 110 may be connected to the integrated circuit 200 through the data link line DLL formed in the third area LA and the data pad DP formed at the end of the circuit film 210, but embodiments of the disclosure are not limited thereto.

Further, the touch line TL for transferring the touch signal may be connected to the integrated circuit 200 through the touch link line TLL of the third area LA and the touch pad TP formed at the end of the circuit film 210.

Electromagnetic noise generated in the data link line DLL disposed in the third area LA while the data signal is transferred may affect the touch sensing link line Y-TLL that transfers the touch sensing signal, thereby deteriorating touch performance.

The display device 100 according to the disclosure may form a shielding layer in an area where the data link line DLL is exposed in the third area LA, thereby reducing an effect of noise caused by the data link line DLL on the touch sensing link line Y-TLL and enhancing touch performance.

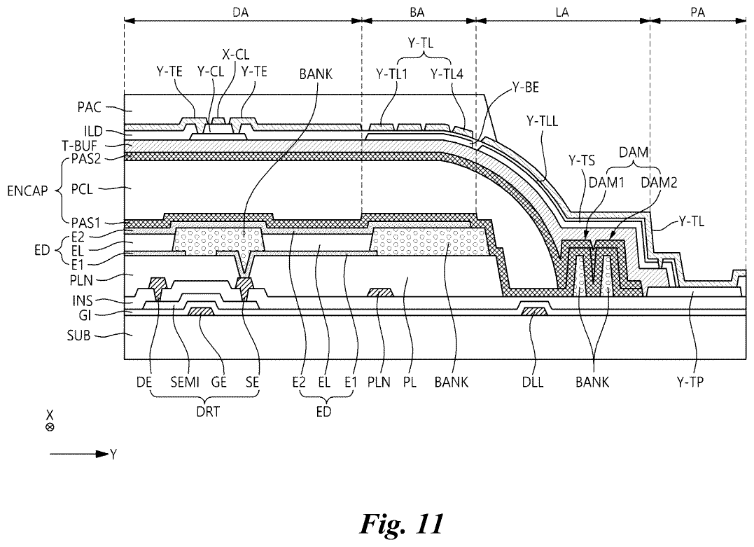

FIG. 11 is a view illustrating an example of a cross section of a display device according to example embodiments of the disclosure.

Referring to FIG. 11, in a display device 100 according to example embodiments of the disclosure, a driving transistor DRT may be disposed on a substrate SUB in a subpixel SP positioned in a display area DA. Here, only the driving transistor DRT is illustrated, but a switching transistor and a storage capacitor included in the subpixel may also be included.

The driving transistor DRT may include a gate electrode GE, a source electrode SE, or a drain electrode DE, and a semiconductor layer SEMI.

The gate electrode GE and the semiconductor layer SEMI may overlap each other with the first insulation layer GI therebetween. The source electrode SE may be formed on the second insulation layer INS to contact one side of the semiconductor layer SEMI, and the drain electrode DE may be formed on the second insulation layer INS to contact the other side of the semiconductor layer SEMI. For example, the semiconductor layer SEMI may include an oxide semiconductor layer, a low temperature polysilicon semiconductor layer, or the like, but embodiments of the disclosure are not limited thereto.

The metal constituting the gate electrode GE may be used as the first signal line. For example, in the process of forming the gate metal GE, it may be used as a signal line for transferring an electrical signal in the display area DA, the first area BA, or the third area LA, without being limited thereto. For example, the metal constituting the gate electrode GE may be used as a data line DL for transferring a data voltage in the display area DA. Further, as an example, the metal constituting the gate electrode GE may be used as a data link line DLL connecting the data line DL and the data pad DP in the third area LA. Embodiments are not limited thereto. As an example, the metal constituting the gate electrode GE may be not used as any signal line.

Meanwhile, as an example, a base shielding layer may be formed between the gate metal GE and the substrate SUB, without being limited thereto. The base shielding layer may not only shield an electric field between the transistor and the substrate SUB, but may also reduce an electrical influence between signal lines.

Further, a second signal line may be formed on the second insulation layer INS. The second signal line may be a power line PL including a high-potential pixel voltage line for transferring a high-potential pixel voltage, a low-potential pixel voltage line for transferring a low-potential pixel voltage, or a reference voltage line for transferring a reference voltage, but embodiments of the disclosure are not limited thereto.

The second signal line may be formed of the same material as the source electrode SE and the drain electrode DE constituting the driving transistor DRT, but embodiments of the disclosure are not limited thereto. The second signal line may extend from the second area PA to the display area DA.

The light emitting element ED may include a first electrode E1, which corresponds to the anode electrode (or cathode electrode), a light emitting layer EL formed on the first electrode E1, and a second electrode E2 formed on the light emitting layer EL and corresponding to the cathode electrode (or anode electrode).

The first electrode E1 may be electrically connected to the source electrode SE of the driving transistor DRT exposed through a contact hole penetrating the third insulation layer PLN. The third insulation layer PLN may be a planarization layer or a protective layer, but embodiments of the disclosure are not limited thereto.

The light emitting layer EL may be disposed on the first electrode E1 of the emission area provided by the bank BANK. The light emitting layer EL may be formed by stacking a hole-related layer, a light emitting layer, and an electron-related layer on the first electrode E1 in the order or in the reverse order. The second electrode E2 may be formed to face the first electrode E1 with the light emitting layer EL interposed therebetween. For example, the hole-related layer may be a hole transporting layer, a hole injection layer, an electron blocking layer, or a P-type charge generation layer, but embodiments of the disclosure are not limited thereto. For example, the electron-related layer may be an electron transporting layer, an electron injection layer, a hole blocking layer, or an N-type charge generation layer, but embodiments of the disclosure are not limited thereto. As an example, at least one or both of the hole-related layer and the electron-related layer may be omitted depending on the design.

The encapsulation layer ENCAP may block external moisture or oxygen from penetrating into the light emitting element ED that is vulnerable to external moisture or oxygen. The encapsulation layer ENCAP may be formed of one layer or may be formed of a multiple stacked structure PAS1, PCL, and PAS2, but embodiments of the disclosure are not limited thereto.

For example, where the encapsulation layer ENCAP is formed of a stacked structure of a plurality of layers PAS1, PCL, and PAS2, the encapsulation layer ENCAP may include one or more inorganic encapsulation layers PAS1 and PAS2 and one or more organic encapsulation layer PCL. For example, in the encapsulation layer ENCAP, the first inorganic encapsulation layer PAS1, the organic encapsulation layer PCL, and the second inorganic encapsulation layer PAS2 may be stacked in the order thereof, but embodiments of the disclosure are not limited thereto.

The organic encapsulation layer PCL may further include at least one organic encapsulation layer or at least one inorganic encapsulation layer, but embodiments of the disclosure are not limited thereto.

The first inorganic encapsulation layer PAS1 may be formed on the substrate SUB where the second electrode E2 corresponding to the cathode electrode is formed to be closest to the light emitting element ED. The first inorganic encapsulation layer PAS1 may be formed of, e.g., an inorganic insulating material such as silicon nitride (SiNx), silicon oxide (SiOx), silicon oxynitride (SiON), or aluminum oxide (Al₂O₃), but embodiments of the disclosure are not limited thereto. Since the first inorganic encapsulation layer PAS1 is deposited in a low-temperature atmosphere, the first inorganic encapsulation layer PAS1 may reduce or prevent the light emitting layer EL including an organic material vulnerable to a high-temperature atmosphere from being damaged during a deposition process.

The organic encapsulation layer PCL may be formed in a smaller area than the first inorganic encapsulation layer PAS1 in which case the organic encapsulation layer PCL may be formed to expose both end tips of the first inorganic encapsulation layer PAS1, without being limited thereto. The organic encapsulation layer PCL serves as a buffer for relieving stress between layers, for example, due to bending of the display device, and may enhance planarization performance. The organic encapsulation layer PCL may be formed of, e.g., an organic insulating material such as an acrylic resin, an epoxy resin, polyimide, polyethylene, or silicon oxycarbon (SiOC), but embodiments of the disclosure are not limited thereto.

When the organic encapsulation layer PCL is formed through an inkjet method, one or more dams DAM may be formed in the first area BA or the third area LA.

For example, the area in which the dam DAM is formed may be a third area LA positioned between the second area PA in which the Y-touch pad Y-TP is formed and the first area BA. In the third area LA, there may be a primary dam DAM1 adjacent to the display area DA and a secondary dam DAM2 adjacent to the second area PA. Embodiments are not limited thereto. As an example, there may be one single dam or three or more dams.

The one or more dams DAM disposed in the third area LA may reduce or prevent the liquid organic encapsulation layer PCL from collapsing toward the first area BA and the third area LA and invading the second area PA when the liquid organic encapsulation layer PCL is formed in the display area DA.

The primary dam DAM1 or the secondary dam DAM2 may be formed in a single-layer structure or multi-layer structure. For example, the primary dam DAM1 or the secondary dam DAM2 may be simultaneously formed of the same material as at least one of the bank BANK and a spacer, but embodiments of the disclosure are not limited thereto. Accordingly, it is possible to form a dam structure without a masking process and an increase in costs. For example, the spacer may be disposed on the bank BANK. For example, the bank BANK may be formed of a material including a black pigment, or an organic material such as a benzocyclobutene resin, a polyimide resin, an acrylic resin, or a photosensitive polymer, but embodiments of the disclosure are not limited thereto. When the bank BANK is formed of a material including a black pigment or a black dye, it may be a black bank. When the bank BANK is formed of a material including a black pigment or a black dye, light from the outside may be blocked, and illuminance of the display device may be further enhanced. The spacer may be formed of the same material as the bank BANK, but embodiments of the disclosure are not limited thereto.

The primary dam DAM1 or the secondary dam DAM2 may have a structure in which the first inorganic encapsulation layer PAS1 and the second inorganic encapsulation layer PAS2 are disposed or stacked on the bank BANK. The organic encapsulation layer PCL including an organic material may be positioned on an inner surface of the primary dam DAM1, may be positioned on an upper portion of at least a portion of the primary dam DAM1, may be positioned between the primary dam DAM1 and the secondary dam DAM2, or may be positioned on an upper portion of at least a portion of the primary dam DAM1 and the secondary dam DAM2.

The second inorganic encapsulation layer PAS2 may be formed over the substrate SUB, where the organic encapsulation layer PCL is formed, to cover the upper surface and side surfaces of the organic encapsulation layer PCL and/or the first inorganic encapsulation layer PAS1. The second inorganic encapsulation layer PAS2 may reduce, minimize or block penetration of external moisture or oxygen into the first inorganic encapsulation layer PAS1 and the organic encapsulation layer PCL. The second inorganic encapsulation layer PAS2 may be formed of, e.g., an inorganic insulating material such as silicon nitride (SiNx), silicon oxide (SiOx), silicon oxynitride (SiON), or aluminum oxide (Al₂O₃), but embodiments of the disclosure are not limited thereto.

A buffer layer T-BUF may be disposed on the encapsulation layer ENCAP. The buffer layer T-BUF may be positioned between the touch sensor metal including the touch electrodes X-TE and Y-TE and the touch electrode connection lines X-CL and Y-CL, and the second electrode E2 of the light emitting element ED.

The buffer layer T-BUF may be designed so that the separation distance between the touch sensor metal and the second electrode E2 of the light emitting element ED maintains a predetermined smallest separation distance (e.g., 1 μm), but embodiments of the disclosure are not limited thereto. Accordingly, it is possible to reduce or prevent the parasitic capacitance formed between the touch sensor metal and the second electrode E2 of the light emitting element ED, thereby reducing or preventing a decrease in touch sensitivity due to the parasitic capacitance.

Without the buffer layer T-BUF, a touch sensor metal including the touch electrodes X-TE and Y-TE and the touch electrode connection lines X-CL and Y-CL may be disposed on the encapsulation layer ENCAP.

The buffer layer T-BUF may reduce or prevent a chemical solution (a developer solution, an etchant solution, or the like) used in the process of manufacturing the touch sensor metal or moisture from the outside from penetrating into the light emitting layer EL including the organic material. Accordingly, the buffer layer T-BUF may reduce or prevent damage to the light emitting layer EL that is vulnerable to a chemical solution or moisture. Accordingly, the buffer layer T-BUF may be formed to cover the touch sensor metal to reduce or prevent the touch sensor metal from being corroded by external moisture or the like.

As an example, the buffer layer T-BUF may be formed of an organic insulating material that may be formed at a low temperature below a predetermined temperature (e.g., 100° C.), without being limited thereto. As an example, the buffer layer T-BUF may be formed of an organic insulating material that has a low dielectric constant. The buffer layer T-BUF may reduce or prevent damage to the light emitting layer EL including an organic material vulnerable to high temperatures. For example, the buffer layer T-BUF may be formed of an acrylic-based material, an epoxy-based material, or a siloxane-based material, but embodiments of the disclosure are not limited thereto.

The buffer layer T-BUF having planarization performance and formed of an organic insulating material may reduce or prevent damage to the inner layers PAS1, PCL, and PAS2 constituting the encapsulation layer ENCAP and breakage of the touch sensor metal formed on the buffer layer T-BUF, for example, as the display device 100 is bent. As another example, the buffer layer T-BUF may not be on the encapsulation layer ENCAP. For example, the buffer layer T-BUF may not be an essential component, and thus may be omitted.

A touch structure may be configured on the encapsulation layer ENCAP. In the case of the mutual capacitance-based touch sensing structure, the X-touch electrode line X-TEL and the Y-touch electrode line Y-TEL may be disposed on the buffer layer T-BUF, and the X-touch electrode line X-TEL and the Y-touch electrode line Y-TEL may be disposed to cross each other, but embodiments of the disclosure are not limited thereto.

The Y-touch electrode line Y-TEL may include a plurality of Y-touch electrode connection lines Y-CL that electrically connect the plurality of Y-touch electrodes Y-TE.

The plurality of Y-touch electrodes Y-TE and the plurality of Y-touch electrode connection lines Y-CL may be positioned on different layers, with a fourth insulation layer ILD interposed therebetween. The fourth insulation layer ILD may be an inter-layer insulation layer, but embodiments of the disclosure are not limited thereto.

The plurality of Y-touch electrodes Y-TE may be spaced apart at a predetermined interval along the y axis direction. The plurality of Y-touch electrodes Y-TE may be electrically connected with another Y-touch electrode Y-TE adjacent thereto in the Y axis direction via the Y-touch electrode connection line Y-CL.

The Y-touch electrode connection line Y-CL may be formed on the buffer layer T-BUF. The Y-touch electrode connection line Y-CL may be exposed via the touch contact hole passing through the fourth insulation layer ILD and be electrically connected with two Y-touch electrodes Y-TE adjacent in the Y axis direction.

As an example, the Y-touch electrode connection line Y-CL may be disposed to overlap the bank BANK. Thus, it is possible to reduce or prevent a reduction in the aperture ratio of the display device due to the Y-touch electrode connection line Y-CL. Embodiments are not limited thereto. As an example, the Y-touch electrode connection line Y-CL may be disposed to at least partially overlap the light emitting element ED. As an example, the Y-touch electrode Y-TE and/or the Y-touch electrode connection line Y-CL may be formed as a mesh-type, without being limited thereto.

The X-touch electrode line X-TEL may include a plurality of X-touch electrode connection lines X-CL that electrically connect the plurality of X-touch electrodes X-TE. The plurality of X-touch electrodes X-TE and the plurality of X-touch electrode connection lines X-CL may be positioned on different layers, with the fourth insulation layer ILD disposed therebetween. Embodiments are not limited thereto. As an example, the plurality of X-touch electrodes X-TE and the plurality of X-touch electrode connection lines X-CL may be positioned on the same layer. As an example, the plurality of X-touch electrodes X-TE and the plurality of X-touch electrode connection lines X-CL may be positioned on the fourth insulation layer ILD as illustrated in FIG. 11, or may be positioned on the buffer layer T-BUF. As an example, the X-touch electrode connection line X-CL may overlap with the Y-touch electrode connection line Y-CL, with the fourth insulation layer ILD interposed therebetween.

The plurality of X-touch electrodes X-TE may be spaced apart at a predetermined interval along the X axis direction, on the fourth insulation layer ILD. The plurality of X-touch electrodes X-TE may be electrically connected with another X-touch electrode X-TE adjacent thereto in the x axis direction via the X-touch electrode connection line X-CL.

The X-touch electrode connection line X-CL may be disposed on the same plane as the X-touch electrode X-TE and be electrically connected with two X-touch electrodes X-TE adjacent thereto in the X axis direction without a separate contact hole or be integrated with the two X-touch electrodes X-TE adjacent thereto in the X axis direction.

The X-touch electrode connection line X-CL may be disposed to overlap the bank BANK. Thus, it is possible to reduce or prevent a reduction in the aperture ratio of the display device due to the X-touch electrode connection line X-CL, without being limited thereto.

The Y-touch electrode line Y-TEL may be electrically connected with the touch driving circuit 152 via the Y-touch line Y-TL and the Y-touch pad Y-TP. The X-touch electrode line X-TEL may be electrically connected with the touch driving circuit 152 via the X-touch line X-TL and the X-touch pad X-TP.

As an example, a cover electrode may be further provided to cover the X-touch pad X-TP and the Y-touch pad Y-TP, without being limited thereto.

The X-touch pad X-TP may be formed separately from the X-touch line X-TL or may extend from the X-touch line X-TL. The Y-touch pad Y-TP may be formed separately from the Y-touch line Y-TL or may extend from the Y-touch line Y-TL.

Where the X-touch pad X-TP extends from the X-touch line X-TL, and the Y-touch pad Y-TP extends from the Y-touch line Y-TL, the X-touch pad X-TP, the X-touch line X-TL, the Y-touch pad Y-TP, and the Y-touch line Y-TL may be formed of the same first conductive material. The first conductive material may be formed in a single layer or multilayer structure using, e.g., a metal having high corrosion resistance and high acid resistance and high conductivity, such as aluminum (Al), titanium (Ti), copper (Cu), or molybdenum (Mo), or transparent conductive material such as ITO or IZO, but embodiments of the disclosure are not limited thereto.

For example, the X-touch pad X-TP, X-touch line X-TL, Y-touch pad Y-TP, and Y-touch line Y-TL formed of the first conductive material may be formed in a three-layer stacked structure, such as Ti/Al/Ti or Mo/Al/Mo, but embodiments of the disclosure are not limited thereto.

The cover electrode capable of covering the X-touch pad X-TP and the Y-touch pad Y-TP may be formed of a second conductive material of the same material as the X-touch electrode X-TE and the Y-touch electrode Y-TE, but embodiments of the disclosure are not limited thereto. The second conductive material may be formed of a transparent conductive material such as ITO or IZO having high corrosion resistance and acid resistance, or may be formed or other conductive materials such as metal, but embodiments of the disclosure are not limited thereto. Since the cover electrode is formed to be exposed by the buffer layer T-BUF, the cover electrode may be bonded (or attached) to the touch driving circuit 150 or may be bonded (or attached) to the circuit film 210 where the touch driving circuit 152 is mounted.

For example, the buffer layer T-BUF may be formed of an organic insulating material or may be formed of a circular polarizing plate or a film formed of an epoxy or acrylic material, but embodiments of the disclosure are not limited thereto. The buffer layer T-BUF may not be on the encapsulation layer ENCAP. For example, the buffer layer T-BUF may not be an essential configuration.

The Y-touch line Y-TL may be electrically connected with the Y-touch electrode via the touch line contact hole or be integrated with the Y-touch electrode Y-TE.

The Y-touch line Y-TL may extend along the upper and side surfaces of the encapsulation layer ENCAP in the first area BA, and may be electrically connected to the Y-touch link line Y-TLL formed on the upper and side surfaces of the dam DAM in the third area LA. Further, the Y-touch link line Y-TLL is electrically connected to the Y-touch pad Y-TP of the second area PA. Accordingly, the Y-touch line Y-TL may be electrically connected to the touch driving circuit 152 through the Y-touch link line Y-TLL and the Y-touch pad Y-TP.

The X-touch line X-TL may receive a touch driving signal from the touch driving circuit 152 and transfer the same to the X-touch electrode X-TE, and the Y-touch line Y-TL may transfer a touch sensing signal generated by the Y-touch electrode Y-TE to the touch driving circuit 152.

As an example, a plurality of Y-touch lines Y-TL1, Y-TL2, Y-TL3, and Y-TL4 may be disposed in the first area BA, and an integrated Y-touch bridge electrode Y-BE may be disposed under the plurality of Y-touch lines Y-TL1, Y-TL2, Y-TL3, and Y-TL4. Embodiments are not limited thereto. As an example, one, two, three, five or more Y-touch lines Y-TL may be disposed in the first area BA, and the Y-touch bridge electrode Y-BE may be disposed under at least one of the one, two, three, five or more Y-touch lines. As an example, the Y-touch lines Y-TL in the first area BA may extend in Y axis direction, X axis direction or any direction between the Y axis direction and the X axis direction, to be connected to the corresponding Y-touch electrode Y-TE or corresponding Y-touch electrode connection line Y-CL in the display area DA and the corresponding Y-touch link line Y-TLL in the third area LA.

As an example, the Y-touch bridge electrode Y-BE may be integrally formed in the first area BA to overlap all of the Y-touch line Y-TL positioned above the Y-touch bridge electrode Y-BE. As an example, the Y-touch bridge electrode Y-BE may be formed to have a width equal to or larger than that of the area occupied by the Y-touch line Y-TL to cover the area occupied by the Y-touch line Y-TL positioned above the Y-touch bridge electrode Y-BE, but embodiments of the disclosure are not limited thereto. As an example, the Y-touch bridge electrode Y-BE may be formed on the same layer as the Y-touch electrode connection line Y-CL, without being limited thereto. As an example, the Y-touch bridge electrode Y-BE may be separated from the Y-touch electrode connection line Y-CL. As an example, the Y-touch bridge electrode Y-BE may have a greater width in the Y axis direction, than the Y-touch electrode connection line Y-CL. As an example, the Y-touch bridge electrode Y-BE may be omitted depending on the design.

As an example, the Y-touch bridge electrode Y-BE in the first area BA may be connected to a constant voltage (e.g., a ground voltage) to discharge the noise charge introduced into the display panel 110. Accordingly, since the noise charge introduced into the display panel 110 is easily discharged to the ground voltage GND, the touch sensing performance of the display device 100 may be enhanced, and defects due to driving of the display may be reduced.

In the third area LA, a Y-shielding layer Y-TS may be disposed between the Y-touch link line Y-TLL and the data link line DLL. The Y-shielding layer Y-TS may be formed on the encapsulation layer ENCAP positioned in the third area LA. As an example, the Y-shielding layer Y-TS may be positioned close to the second area PA or close to the first area BA according to the structure of the data link line DLL, without being limited thereto. As an example, the Y-shielding layer Y-TS may be disposed on the same layer as the Y-touch bridge electrode Y-BE, without being limited thereto. As an example, the Y-shielding layer Y-TS may be disposed on the same layer as Y-touch electrode connection line Y-CL, without being limited thereto. As an example, the Y-shielding layer Y-TS may be disposed on the buffer layer T-BUF, without being limited thereto. As an example, the Y-shielding layer Y-TS may have a greater width in the Y axis direction, than the Y-touch electrode connection line Y-CL, without being limited thereto. As an example, the Y-shielding layer Y-TS may have a greater width in the Y axis direction, than the Y-touch bridge electrode Y-BE, without being limited thereto.

The Y-shielding layer Y-TS may be formed on the buffer layer T-BUF. Accordingly, electromagnetic noise caused by the data link line DLL may be reduced or prevented from affecting the Y-touch link line Y-TLL.

As an example, the Y-shielding layer Y-TS may be connected to a constant voltage, such as a low-potential pixel voltage line (e.g., a ground voltage) to emit electromagnetic noise. Accordingly, since the noise charge introduced by the data link line DLL is easily discharged to the ground voltage, the touch sensing performance of the display device 100 may be enhanced, and defects due to driving of the display may be reduced. As an example, the Y-shielding layer Y-TS may be connected the same low-potential pixel voltage line as the Y-touch bridge electrode Y-BE, without being limited thereto. As an example, the Y-shielding layer Y-TS and the Y-touch bridge electrode Y-BE may be configured to receive the same voltage or different voltages. As an example, the Y-shielding layer Y-TS may be connected to or integrated with the Y-touch bridge electrode Y-BE, or may be separated with the Y-touch bridge electrode Y-BE.

The Y-touch link line Y-TLL and the Y-shielding layer Y-TS may be insulated by the fourth insulation layer ILD disposed therebetween.

The X-touch line X-TL may be electrically connected to the X-touch electrode X-TE through a touch contact hole or may be integrally configured with the X-touch electrode X-TE, but embodiments of the disclosure are not limited thereto.

The X-touch line X-TL may extend along the upper and side surfaces of the encapsulation layer ENCAP in the first area BA, and may be electrically connected to the X-touch link line X-TLL formed on the upper and side surfaces of the dam DAM in the third area LA. Further, the X-touch link line X-TLL is electrically connected to the X-touch pad X-TP of the second area PA. Accordingly, the X-touch line X-TL may be electrically connected to the touch driving circuit 152 through the X-touch link line X-TLL and the X-touch pad X-TP.

The X-touch line X-TL may receive a touch driving signal from the touch driving circuit 152 and transfer the same to the X-touch electrode X-TE.

The arrangement of the X-touch line X-TL and the Y-touch line Y-TL may be variously changed according to the design of the display panel 110.

A touch protection film PAC may be disposed on the X-touch electrode X-TE and the Y-touch electrode Y-TE. The touch protection film PAC may extend to the first area BA and the third area LA and may be disposed on the X-touch line X-TL and the Y-touch line Y-TL. Further, the touch protection film PAC may extend to an upper portion of the dam DAM of the third area LA.

The cross-sectional view illustrated herein illustrates the structure of the display device 100, and the position, thickness, or width of each pattern (various layers or various electrodes) may vary depending on the viewing direction or position, the connection structure of various patterns may also be changed, there may be additional layers in addition to the illustrated layers, and some of the illustrated layers may be omitted or integrated. For example, the width of the bank BANK may be narrower than that shown in the drawings, and the height of the dam DAM may be lower or higher than that shown in the drawings, but embodiments of the disclosure are not limited thereto.

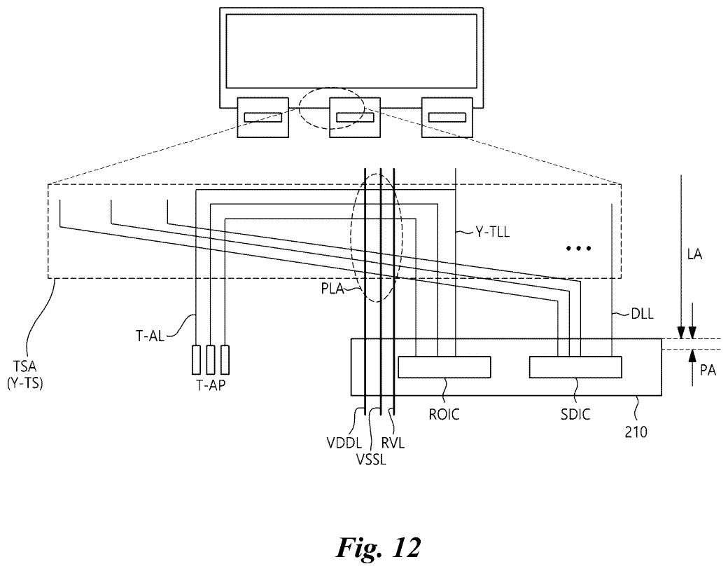

FIG. 12 is a plan view illustrating an example of a third area in a display device according to example embodiments of the disclosure.

Referring to FIG. 12, in a display device 100 according to example embodiments of the disclosure, one side of a circuit film 210 where a plurality of integrated circuits are mounted may be electrically connected to the display panel 110.

The integrated circuit may include at least one data driving integrated circuit SDIC and at least one touch driving integrated circuit ROIC. The data driving integrated circuit SDIC and the touch driving integrated circuit ROIC may be integrated or separately configured, and an example where the data driving integrated circuit SDIC and the touch driving integrated circuit ROIC are separately configured is illustrated, but embodiments of the disclosure are not limited thereto.

The data link line DLL formed in the third area LA may connect the data pad DP formed in the data driving integrated circuit SDIC and the data line DL of the display area DA.

The data driving integrated circuit SDIC mounted on the circuit film 210 may supply a data signal to the display area DA of a wide area. Accordingly, the plurality of data link lines DLL extending from the data driving integrated circuit SDIC may extend diagonally in the third area LA.

Noise generated in the data link line DLL extending diagonally from the third area LA may affect the upper Y-touch link line Y-TLL. For example, due to the noise generated from the data link line DLL, the touch sensing signal transferred through the Y-touch link line Y-TLL may be distorted, rendering accurate touch sensing difficult.

Accordingly, a fourth area TSA may be configured along a direction in which the data link line DLL extends in the third area LA. A Y-shielding layer Y-TS may be formed in the fourth area TSA. The fourth area TSA may be a touch shield area or a shield area, but embodiments of the disclosure are not limited thereto. As an example, the fourth area TSA may be configured to overlap at least a portion or the entirety of the area in which the data link line DLL extends in the third area LA, without being limited thereto. As an example, the fourth area TSA may be configured to overlap at least a portion or the entirety of the data link line DLL extending in the third area LA, without being limited thereto. As an example, the fourth area TSA may be configured to overlap at least a portion or the entirety of an area where the data link line DLL crosses the Y-touch link line Y-TLL, without being limited thereto.

The Y-shielding layer Y-TS may be formed between the Y-touch link line Y-TLL and the data link line DLL. The Y-shielding layer Y-TS may be formed of the same material as the Y-touch bridge electrode Y-BE formed under the Y-touch line Y-TL, but embodiments of the disclosure are not limited thereto. In this case, the Y-shielding layer Y-TS may be formed through the same process as the Y-touch bridge electrode Y-BE, but embodiments of the disclosure are not limited thereto.

The fourth area TSA in which the Y-shielding layer Y-TS is formed may be formed along a direction in which the data link line DLL extends. For example, when the data link line DLL extends in a horizontal diagonal direction, the fourth area TSA may be formed along the horizontal direction at a position overlapping at least a portion of the data link line DLL.

The fourth area TSA may be formed to overlap at least a portion of the Y-touch link line Y-TLL.

The Y-touch link line Y-TLL may be connected to the Y-touch pad Y-TP formed in the touch driving integrated circuit ROIC mounted on the circuit film 210. Further, as an example, the Y-touch link line Y-TLL may be connected to the touch inspection line T-AL extending from the touch inspection pad T-AP, without being limited thereto.

Accordingly, the fourth area TSA may be formed to overlap at least a portion of the touch inspection line Y-AL, without being limited thereto.

A power line such as a high-potential pixel voltage line VDDL for transferring a high-potential pixel voltage, a low-potential pixel voltage line VSSL for transferring a low-potential pixel voltage, and a reference voltage line RBL for transferring a reference voltage may be disposed on a side portion of the circuit film 210.

As an example, the power line may be disposed between the data link line DLL and the Y-touch link line Y-TLL in a thickness direction, without being limited thereto. Accordingly, in a sixth area PLA, noise generated in the data link line DLL may be blocked without being transferred to the Y-touch link line Y-TLL. Accordingly, in the sixth area PLA, the noise of the data link line DLL may be blocked by the power line, and thus the Y-shielding layer Y-TS may be open without being formed. The sixth area PLA may be a line area or a power line area, but embodiments of the disclosure are not limited thereto. As an example, the sixth area PLA may be an area where the power line is disposed in the third area LA. Embodiments are not limited thereto. As an example, even in the sixth area PLA, the Y-shielding layer Y-TS may be also formed.

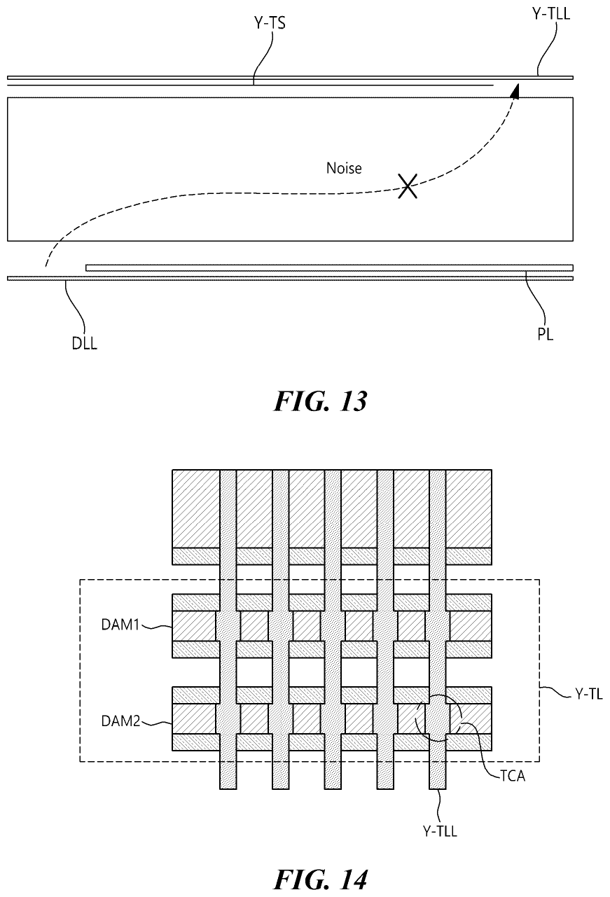

FIG. 13 is a view illustrating a cross section of a portion of a fourth area in a display device according to example embodiments of the disclosure.

Referring to FIG. 13, in a display device 100 according to example embodiments of the disclosure, a Y-shielding layer Y-TS may be formed under a Y-touch link line Y-TLL where a touch sensing signal is transferred in a fourth area TSA of a third area LA.

The Y-shielding layer Y-TS is formed at a position overlapping at least a portion of the data link line DLL. Accordingly, the data link line DLL does not directly overlap the Y-touch link line Y-TLL in the vertical direction. Accordingly, it may be difficult for the noise caused by a data signal transferred along the data link line DLL to be transferred to the Y-touch link line Y-TLL. The noise caused by the data signal transferred along the data link line DLL may decrease as the distance between the open data link line DLL and the Y-touch link line Y-TLL increases.

Accordingly, the touch sensing signal transferred through the Y-touch link line Y-TLL is not affected by noise caused by the data signal, and thus accurate touch sensing may be performed in the touch driving integrated circuit ROIC.

When the power line PL is positioned above the data link line DLL, noise caused by the data link line DLL may be more effectively blocked. Accordingly, the Y-shielding layer Y-TS may be open in at least a portion of the area in which the power line PL is formed.

The display device 100 according to the disclosure may enhance touch performance by securing reliability of a touch sensing signal by adjusting the line width of the Y-touch link line Y-TLL on the dam DAM positioned in the third area LA.

FIG. 14 is a plan view illustrating a Y-touch link line extending along a third area in a display device according to example embodiments of the disclosure.

Referring to FIG. 14, in a display device 100 according to example embodiments of the disclosure, a dam DAM protruding from a lower surface may be disposed in a third area LA of a display panel 110.

The dam DAM may be disposed in a direction parallel to the outer periphery of the display panel 110 to reduce or prevent the encapsulation layer ENCAP from collapsing. As the dam DAM, e.g., two dams DAM1 and DAM2 may be disposed adjacent to each other, but embodiments of the disclosure are not limited thereto.

The Y-touch link line Y-TLL may be disposed in the third area LA to connect the Y-touch line Y-TL connected to the Y-touch electrode line Y-TEL and the touch driving integrated circuit ROIC. The Y-touch link line Y-TLL extending along the third area LA may be disposed in a direction of crossing the dam DAM positioned outside the display panel 110. For example, the Y-touch link line Y-TLL may be disposed in a direction of crossing the dam DAM and may be disposed across the dam DAM.

In the process in which the Y-touch link line Y-TLL is formed along the shape of the dam DAM having a step, the residual film of the photoresist used to etch the encapsulation layer ENCAP may remain at the lower boundary of the dam DAM due to a high step in the area in which the dam DAM is disposed. As described above, in the area in which the residual film of the photoresist remains, a short circuit may occur between two adjacent Y-touch link lines Y-TLL.

Further, since the dam DAM formed outside the display panel 110 protrudes upward, the thickness of the Y-touch link line Y-TLL passing through the protruding area above the dam DAM may be reduced, so that the Y-touch link line Y-TLL may be disconnected.

Accordingly, in order to reduce or prevent disconnection of the Y-touch link line Y-TLL, a fifth area TCA in which the line width of the Y-touch link line Y-TLL positioned above the dam DAM is extended in the length direction of the dam DAM may be included. The fifth area TCA may be a compensation area or a touch line compensation area, but embodiments of the disclosure are not limited thereto.

In this case, since the line width of the Y-touch link line Y-TLL positioned on the upper portion of the dam DAM is larger than the line width of the other portion, it is possible to reduce or prevent the Y-touch link line Y-TLL from being disconnected even if the thickness of the Y-touch link line Y-TLL decreases in a partial section of the upper portion of the dam DAM.

The fifth area TCA may be formed in a process of forming the Y-touch link line Y-TLL on the encapsulation layer ENCAP.

Further, by forming the fifth area TCA so that the line width of the Y-touch link line Y-TLL positioned above the dam DAM is extended in the length direction of the dam DAM, a short circuit and disconnection of the Y-touch link line Y-TLL may be reduced or prevented.

The fifth area TCA in which the line width of the Y-touch link line Y-TLL is extended may be easily affected by noise caused by the data link line DLL.

Accordingly, by forming the Y-shielding layer Y-TS in the fifth area TCA in which the line width of the Y-touch link line Y-TLL is extended, the influence of noise on the Y-touch link line Y-TLL by the data link line DLL may be reduced. Accordingly, the fourth area TSA in which the Y-shielding layer Y-TS is formed may include the fifth area TCA in which the line width of the Y-touch link line Y-TLL is extended.

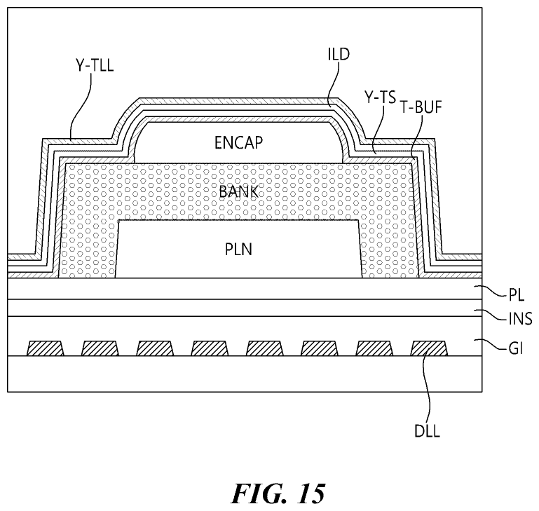

FIG. 15 is a view illustrating a portion of a cross section taken along a direction in which a dam extends in a third area in a display device according to example embodiments of the disclosure.

Referring to FIG. 15, in a display device 100 according to example embodiments of the disclosure, one or more dams DAM protruding from a lower surface may be formed in the third area LA of the display panel 110.

A data link line DLL connecting the data line DL and the data pad DP may be disposed on the substrate SUB in the third area LA. The data link line DLL may be a first signal line. The data link line DLL may be formed of the same material as the data line DL of the display area DA, but embodiments of the disclosure are not limited thereto.

The first insulation layer GI and the second insulation layer INS may be positioned above the data link line DLL to cover the data link line DLL.

A power line PL including a high-potential pixel voltage line VDDL for transferring a high-potential pixel voltage, a low-potential pixel voltage line VSSL for transferring a low-potential pixel voltage, or a reference voltage line RVL for transferring a reference voltage may be formed on the second insulation layer INS, but embodiments of the disclosure are not limited thereto. The power line PL may be a second signal line.

A third insulation layer PLN and a bank BANK covering the third insulation layer PLN may be formed on the upper portion of the power line PL to have a step. Further, an encapsulation layer ENCAP having a width smaller than that of the bank BANK may be disposed above the bank BANK, forming a dam DAM.

The buffer layer T-BUF may be disposed to cover the dam DAM, and the Y-shielding layer Y-TS may be disposed above the buffer layer T-BUF.

A fourth insulation layer ILD may be disposed on the Y-shielding layer Y-TS, and a Y-touch link line Y-TLL may be formed on the fourth insulation layer ILD. Accordingly, the Y-shielding layer Y-TS and the Y-touch link line Y-TLL may be insulated by the fourth insulation layer ILD.

A touch protection film PAC may be disposed on the Y-touch link line Y-TLL.

The display device 100 according to the disclosure may reduce or prevent the noise of the data link line DLL from being transferred to the Y-touch link line Y-TLL by the Y-shielding layer Y-TS disposed between the Y-touch link line Y-TLL and the data link line DLL in the third area LA.

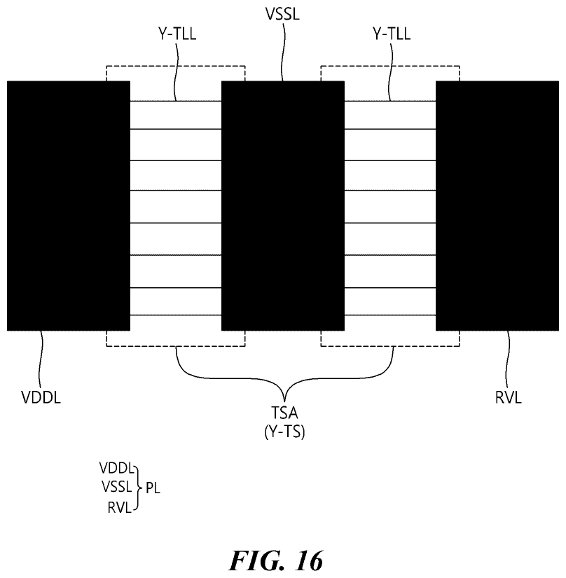

FIG. 16 is a plan view illustrating a portion where a power line is disposed in a third area in a display device according to example embodiments of the disclosure.

Referring to FIG. 16, in a display device 100 according to example embodiments of the disclosure, one or more power lines PL may be disposed along a side portion of a circuit film 210 where an integrated circuit 200 is mounted.

The power line PL may include a high-potential pixel voltage line VDDL for transferring a high-potential pixel voltage, a low-potential pixel voltage line VSSL for transferring a low-potential pixel voltage, and a reference voltage line RVL for transferring a reference voltage, but embodiments of the disclosure are not limited thereto.

The power line PL may be disposed between the data link line DLL and the Y-touch link line Y-TLL to block noise generated in the data link line DLL from being transferred to the Y-touch link line Y-TLL.

Accordingly, the Y-shielding layer Y-TS may be open without being formed in the sixth area PLA in which the power line PL is formed. However, when the Y-touch link line Y-TLL is positioned along the area between the power lines PL, the Y-shielding layer Y-TS may be formed to cover the area between the power lines PL.

For example, the fourth area TSA in which the Y-shielding layer Y-TS is formed may include the area between the power lines PL. The fourth area TSA in which the Y-shielding layer Y-TS is formed may include a sixth area PLA in which the power line PL is formed.

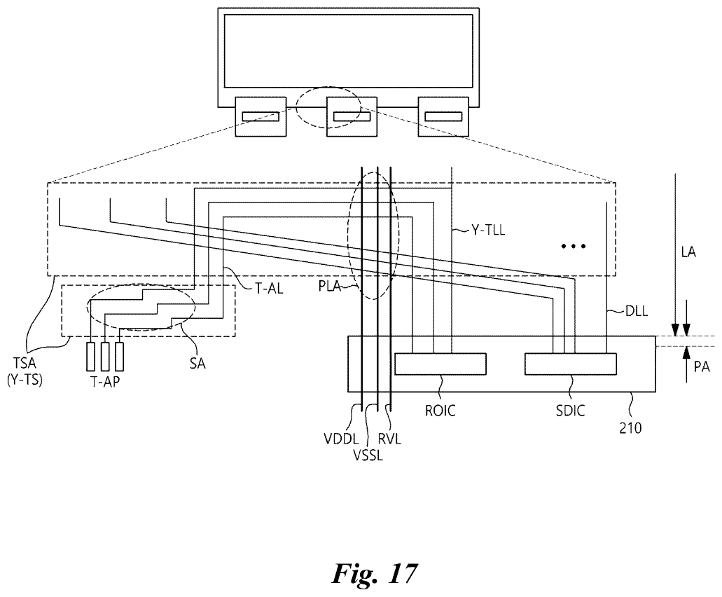

FIG. 17 is a plan view illustrating another example of a third area in a display device according to example embodiments of the disclosure.

FIG. 17 illustrates a case in which the touch inspection line T-AL adjacent to the touch inspection pad T-AP of the third area LA in FIG. 12 has a different structure.

Referring to FIG. 17, in the display device 100 according to example embodiments of the disclosure, one side of the circuit film 210 where the plurality of integrated circuits 200 are mounted may be electrically connected to the display panel 110.

The data link line DLL formed in the third area LA may connect the data pad DP formed in the data driving integrated circuit SDIC and the data line DL of the display area DA.

The data driving integrated circuit SDIC mounted on the circuit film 210 supplies a data signal to the display area DA of a wide area. Accordingly, the plurality of data link lines DLL extending from the data driving integrated circuit SDIC may extend diagonally in the third area LA.

Noise generated in the data link line DLL extending diagonally from the third area LA may affect the upper Y-touch link line Y-TLL. As an example, due to the noise generated in the data link line DLL, the touch sensing signal transferred through the Y-touch link line Y-TLL may be distorted, rendering accurate touch difficult.

The Y-touch link line Y-TLL may be connected to the Y-touch pad Y-TP formed in the touch driving integrated circuit ROIC mounted on the circuit film 210. Further, the Y-touch link line Y-TLL may be connected to the touch inspection line T-AL extending from the touch inspection pad T-AP.

Accordingly, the noise generated in the data link line DLL may be transferred to the Y-touch link line Y-TLL through the touch inspection line T-AL.

Larger noise may be generated in a structure in which the touch inspection pad T-AP is formed on the display panel 110.

Accordingly, by forming the touch inspection line T-AL adjacent to the touch inspection pad T-AP in a stepped structure, the separation distance from the data link line DLL may be increased and the influence of noise may be reduced. For example, an area adjacent to the touch inspection pad T-AP may include a seventh area SA in which the touch inspection line T-AL is formed in a stepped structure. The seventh area SA may be an inspection area or a touch inspection area, but embodiments of the disclosure are not limited thereto.

The touch inspection line T-AL may be increased in length due to the stepped structure. Accordingly, it may be easily affected by the noise caused by the data link line DLL.

Accordingly, when the touch inspection line T-AL is formed in a stepped structure, the fourth area TSA may be formed to include at least a portion of the seventh area SA of the touch inspection line T-AL, thereby reducing the noise influence caused by the data link line DLL.

Example embodiments of the disclosure are described below.

A display device according to the disclosure may comprise a display area where a plurality of subpixels and a plurality of touch electrodes are disposed, a first area where a plurality of data lines and a plurality of touch lines are disposed, a second area where a plurality of data pads and a plurality of touch pads are disposed, and a third area where a plurality of data link lines and a plurality of touch link lines are disposed, between the first area and the second area. The third area may include a fourth area between the plurality of data link lines and the plurality of touch link lines and where a shielding layer is disposed to overlap at least some of the plurality of data link lines.

According to an example embodiment of the disclosure, the plurality of touch lines may be touch sensing lines through which a touch sensing signal is transferred from the plurality of touch electrodes.

According to an example embodiment of the disclosure, the first area may include a plurality of touch bridge electrodes electrically connected to the plurality of touch lines under the plurality of touch lines.

According to an example embodiment of the disclosure, the shielding layer may be formed of the same material as the touch bridge electrode.

According to an example embodiment of the disclosure, the third area may include at least one dam. The plurality of touch link lines may include a fifth area in which a different line width increases in a length direction of the dam on an upper portion of the at least one dam.

According to an example embodiment of the disclosure, the fourth area may be disposed to overlap the fifth area.

According to an example embodiment of the disclosure, the third area may include a sixth area where a plurality of power lines are disposed between the plurality of data link lines and the plurality of touch link lines. The fourth area may be open in the sixth area.

According to an example embodiment of the disclosure, the third area may include a plurality of touch inspection lines connecting the plurality of touch link lines to a plurality of touch inspection pads. The plurality of touch inspection lines may include a seventh area configured in a stepped structure in an area adjacent to the plurality of touch inspection pads.

According to an example embodiment of the disclosure, the fourth area may be disposed to overlap at least a portion of the seventh area.

According to an example embodiment of the disclosure, the plurality of touch inspection pads may be formed on the display panel.

A display device according to the disclosure may comprise a substrate, a first signal line disposed on the substrate, a first insulation layer disposed to cover the first signal line, a second insulation layer disposed on the first insulation layer, a second signal line disposed on the second insulation layer, a third insulation layer formed on the second signal line, a bank having a step and covering the third insulation layer, an encapsulation layer formed on the bank to have a width smaller than the bank to form a dam, a buffer layer disposed to cover the encapsulation layer, a shielding layer disposed on the buffer layer, a fourth insulation layer disposed on the shielding layer, and a touch link line formed on the fourth insulation layer.

According to an example embodiment of the disclosure, the first signal line may be a data link line transferring a data signal.

According to an example embodiment of the disclosure, the second signal line may be a power line transferring one or more of a high-potential pixel voltage, a low-potential pixel voltage, and a reference voltage.

According to an example embodiment of the disclosure, the touch link line may include a fifth area having a different line width in a length direction of the dam on an upper portion of the dam.

According to an example embodiment of the disclosure, the shielding layer may be disposed to overlap the fifth area.

According to an example embodiment of the disclosure, the shielding layer may be open in an area where the second signal line is disposed.

According to an example embodiment of the disclosure, the display device may further comprise a touch inspection line connecting the touch link line to a touch inspection pad. The touch inspection line may be configured in a stepped structure in an area adjacent to the touch inspection pad.

According to an example embodiment of the disclosure, the shielding layer may be disposed to overlap at least a portion of the stepped structure.

A display panel according to the disclosure may comprise a display area where a plurality of subpixels and a plurality of touch electrodes are disposed, a first area where a plurality of data lines and a plurality of touch lines are disposed, a second area where a plurality of data pads and a plurality of touch pads are disposed, and a third area where a plurality of data link lines and a plurality of touch link lines are disposed, between the first area and the second area. The third area may include a fourth area between the plurality of data link lines and the plurality of touch link lines and where a shielding layer is disposed to overlap at least some of the plurality of data link lines.

A display device according to various example embodiments of the disclosure may be applied to mobile devices, video phones, smart watches, watch phones, wearable devices, foldable devices, rollable devices, bendable devices, flexible devices, curved devices, slidable devices, transformable devices, electronic notebooks, electronic books, portable multimedia players (PMPs), personal digital assistants (PDAs), MP3 players, mobile medical devices, desktop PCs, laptop PCs, netbook computers, workstations, navigation devices, vehicle navigations, vehicle displays, vehicle devices, theater devices, theater displays, televisions, wallpaper devices, signage devices, game consoles, laptop computers, monitors, cameras, camcorders, and home appliances.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display area including a plurality of subpixels and a plurality of touch electrodes;
a first area including a plurality of data lines and a plurality of touch lines;
a second area including a plurality of data pads and a plurality of touch pads; and
a third area between the first area and the second area, the third area including a plurality of data link lines and a plurality of touch link lines,
wherein the third area includes a fourth area where a shielding layer is disposed between the plurality of data link lines and the plurality of touch link lines in a thickness direction of the display device and overlaps at least some of the plurality of data link lines.

2. The display device of claim 1, wherein the plurality of touch lines are touch sensing lines through which a touch sensing signal is configured to be transferred from the plurality of touch electrodes.

3. The display device of claim 1, wherein the first area includes a touch bridge electrode under the plurality of touch lines.

4. The display device of claim 3, wherein the shielding layer is formed of a same material as the touch bridge electrode.

5. The display device of claim 3, wherein the touch bridge electrode is configured to receive a ground voltage.

6. The display device of claim 1, wherein the third area includes at least one dam, and wherein a portion of the touch link line on an upper portion of the at least one dam has a different line width in a length direction of the dam.

7. The display device of claim 6, wherein the shielding layer overlaps the portion of the touch link line.

8. The display device of claim 1, wherein the third area includes a sixth area where a plurality of power lines are disposed between the plurality of data link lines and the plurality of touch link lines in the thickness direction, and
wherein the shielding layer is open in the sixth area.

9. The display device of claim 1, wherein the third area includes a plurality of touch inspection lines connecting the plurality of touch link lines to a plurality of touch inspection pads, and
wherein the plurality of touch inspection lines includes a stepped structure in a seventh area adjacent to the plurality of touch inspection pads.

10. The display device of claim 9, wherein the shielding layer overlaps at least a portion of the seventh area.

11. The display device of claim 9, wherein the plurality of touch inspection pads are formed on a display panel of the display device.

12. The display device of claim 1, wherein each of the plurality of touch link lines connects one of the plurality of touch lines in the first area to corresponding one of the plurality of touch pads in the second area, and
each of the plurality of data link lines connects one of the plurality of data lines in the first area to corresponding one of the plurality of data pads in the second area.

13. The display device of claim 1, wherein the plurality of touch electrodes include touch electrodes and touch electrode connection lines connecting two adjacent touch electrodes in a same column,
wherein the touch electrodes and the touch electrode connection lines are disposed on different layers, and
wherein the shielding layer is formed of a same material on a same layer as the touch electrode connection lines.

14. The display device of claim 1, wherein the shielding layer is connected to a low-potential pixel voltage line.

15. The display device of claim 1, wherein the plurality of data link lines extend diagonally in the third area, and
the fourth area is configured along a direction in which the data link line extends in the third area.

16. The display device of claim 1, wherein the shielding layer overlaps an area where the data link lines and the touch link lines crosses each other.

17. The display device of claim 1, wherein the data pad and the touch pad are formed on a circuit film electrically connected to a display panel of the display device.

18. A display device, comprising:
a substrate;
a first signal line disposed on the substrate;
a first insulation layer disposed on the first signal line;
a second signal line disposed on the first insulation layer;
a third insulation layer disposed on the second signal line;
a bank disposed on the third insulation layer;
an encapsulation layer on the bank and including a dam;
a buffer layer disposed on the encapsulation layer;
a shielding layer disposed on the buffer layer;
a fourth insulation layer disposed on the shielding layer; and
a touch link line disposed on the fourth insulation layer.

19. The display device of claim 18, wherein the first signal line is a data link line configured to transfer a data signal.

20. The display device of claim 18, wherein the second signal line is a power line configured to transfer one or more of a high-potential pixel voltage, a low-potential pixel voltage, or a reference voltage.

21. The display device of claim 18, wherein a portion of the touch link line on an upper portion of the dam has a different line width in a length direction of the dam.

22. The display device of claim 21, wherein the shielding layer overlaps the portion of the touch link line.

23. The display device of claim 18, wherein the shielding layer is open in an area where the second signal line is disposed.

24. The display device of claim 18, further comprising a touch inspection line connecting the touch link line to a touch inspection pad,
wherein the touch inspection line includes a stepped structure in an area adjacent to the touch inspection pad.

25. The display device of claim 24, wherein the shielding layer overlaps at least a portion of the stepped structure.

26. The display device of claim 18, wherein the encapsulation layer has a width smaller than the bank.

27. A display panel, comprising:
a display area including a plurality of subpixels and a plurality of touch electrodes;
a first area including a plurality of data lines and a plurality of touch lines;
a second area including a plurality of data pads and a plurality of touch pads; and
a third area between the first area and the second area, the third area including a plurality of data link lines and a plurality of touch link lines,
wherein the third area includes a fourth area where a shielding layer is disposed between the plurality of data link lines and the plurality of touch link lines in a thickness direction of the display panel and overlaps at least some of the plurality of data link lines.
